(19) United States
(12) Patent Application Publication
(10) Pub. No.: US 2024/0206146 A1
(43) Pub. Date: Jun. 20, 2024

(54) METHOD FOR PRODUCING PILLAR-SHAPED SEMICONDUCTOR DEVICE

(71) Applicant: Unisantis Electronics Singapore Pte. Ltd., Singapore (SG)

(72) Inventors: Kenichi KANAZAWA, Tokyo (JP); Yisuo LI, Tokyo (JP)

(21) Appl. No.: 18/588,958

(22) Filed: Feb. 27, 2024

Related U.S. Application Data
(63) Continuation-in-part of application No. PCT/JP2021/031871, filed on Aug. 31, 2021.

(51) Int. Cl. H10B 10/00; H01L 21/306

(52) U.S. Cl. CPC H10B 10/125; H01L 21/30608

(57) ABSTRACT

A method for producing a pillar-shaped semiconductor device having both a CSGT mainly used in a memory cell and an ESGT used in a peripheral circuit is proposed. For a highly integrated CSGT, patterning is used 2 times in total in the X-direction and the Y-direction perpendicular to each other to form the CSGT in an overlap of band-shaped sidewalls each formed in each patterning. For an ESGT, two rectangular frame-shaped sidewalls are formed at desired positions, and the ESGT is formed in an overlap of the sidewalls. This enables formation of both the CSGT and the ESGT in the same production process under the same production conditions.

### CROSS REFERENCES TO RELATED APPLICATIONS

The present application is a continuation-in-part application of PCT/JP2021/031871, filed Aug. 31, 2021, the entire contents of which are incorporated herein by reference.

### BACKGROUND OF THE INVENTION

### 1. Field of the Invention

The present invention relates to a method for producing a pillar-shaped semiconductor device.

### 2. Description of the Related Art

Three-dimensional transistors have recently been used in large-scale integration (LSI). In particular, surrounding gate transistors (SGTs), which are pillar-shaped semiconductor devices, have attracted attention as semiconductor elements that provide highly integrated semiconductor devices. There has been a need of SGT-including semiconductor devices with higher integration and higher performance.

In a typical planar MOS transistor, a channel extends horizontally along the upper surface of a semiconductor substrate. In an SGT, a channel extends vertically from the upper surface of a semiconductor substrate (see, for example, Japanese Unexamined Patent Application Publication No. 2-188966, and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Thus, SGTs can provide higher-density semiconductor devices than planar MOS transistors.

FIG. 5A is a schematic structural view of an n-channel SGT. A semiconductor pillar 220 having p-type or i-type (intrinsic) conductivity includes, in its upper and lower portions, n⁺-layers 221a and 221b, one of which serves as a source, and the other one of which serves as a drain (hereinafter, a semiconductor region containing a high concentration of donor impurity is referred to as an “n⁺-layer”). A portion of the semiconductor pillar 220 between the n⁺-layers 221a and 221b, which serve as a source and a drain, is a channel region 222. The channel region 222 is surrounded by a gate insulating layer 223. The gate insulating layer 223 is surrounded by a gate conductor layer 224. In the SGT, the n⁺-layers 221a and 221b, which serve as a source and a drain, the channel region 222, the gate insulating layer 223, and the gate conductor layer 224 are generally formed in a pillar shape. In plan view, the area occupied by the SGT thus corresponds to the area occupied by a single source or drain n⁺-layer of a planar MOS transistor. Therefore, SGT-including circuit chips have a smaller size than circuit chips including planar MOS transistors. As the drive capacity of SGTs increases, the number of SGTs used per chip decreases, and the chip size decreases accordingly.

FIG. 6 is a circuit diagram of a static random access memory (SRAM) cell. The SRAM cell circuit includes two inverter circuits. The sources of p-channel SGTs Pc1 and Pc2 are connected to a power supply terminal Vdd. The sources of n-channel SGTs Nc1 and Nc2 are connected to a ground terminal Vss. Selection n-channel SGTs SN1 and SN2 are disposed on both sides of the two inverter circuits. The gates of the selection n-channel SGTs SN1 and SN2 are connected to a word line terminal WLt. The source and drain of the selection n-channel SGT SN1 are connected to the drains of the n-channel SGT Nc1 and the p-channel SGT Pc1 and a bit line terminal BLt, respectively. The source and drain of the selection n-channel SGT SN2 are connected to the drains of the n-channel SGT Nc2 and the p-channel SGT Pc2 and a reverse bit line terminal BLRt, respectively. The SRAM cell-including circuit includes six SGTs in total: two p-channel SGTs Pc1 and Pc2, and four n-channel SGTs Nc1, Nc2, SN1, and SN2.

To reduce the cell area and increase the degree of integration, an SRAM cell includes a circular SGT (CSGT) as illustrated in FIG. 5A. A peripheral circuit, which requires current drive capability, has low current drive capability when having a single circular SGT, and thus needs to include multiple CSGTs connected in parallel to compensate for insufficient current drive capability. However, this configuration requires a significant large area and hinders high integration. To solve this issue, an elongated SGT (ESGT) as illustrated in FIG. 5B has been proposed. However, forming both CSGTs and ESGTs is a significant challenge. The reason for this is as described below. CSGTs have the following features: they are mainly used in memory cells and regularly arranged while having fine semiconductor pillars with the same size. Self-aligned double patterning (SADP) commonly used in miniaturization processing is used for CSGTs. ESGTs have the following features: they are mainly used in peripheral circuits and randomly arranged while having various lengths. These features are contradictory to those of CSGTs and incompatible with SADP. Therefore, forming both CSGTs and ESGTs poses production challenges. (For example, U.S. Patent Application Publication No. 2010/0219483, U.S. Pat. No. 8,530,960, and C. Y. Ting, V. J. Vivalda, and H. G. Schaefer: “Study of planarized sputter-deposited SiO₂”, J. Vac. Sci. Technol. 15(3), p.p. 1105-1112, May/June (1978), and A. Raley, S. Thibaut, N. Mohanty, K. Subhadeep, S. Nakamura, et. al,: “Self-aligned quadruple patterning integration using spacer on spacer pitch splitting at the resist level for sub-32 nm pitch applications” Proc. Of SPIE Vol. 9782, 2016.)

### SUMMARY OF THE INVENTION

It is very difficult to produce both CSGTs, which are used in memory cells to improve the degree of integration, and ESGTs, which are used in peripheral circuits to improve the drive capacity, at the same time when mounting both CSGTs and ESGTs in SGT-including memory semiconductors because CSGTs and ESGTs have different features in terms of layout and shape.

A first method for producing a pillar-shaped semiconductor device according to an aspect of the present invention is
a method for producing a pillar-shaped semiconductor device having both a circular SGT (CSGT) and an elongated SGT (ESGT) on a substrate,
wherein the pillar-shaped semiconductor device includes: on the substrate, a first semiconductor pillar region having a first semiconductor pillar with a CSGT shape, and a second semiconductor pillar region having a second semiconductor pillar with an ESGT shape; a first gate insulating layer around the first semiconductor pillar; a second gate insulating layer around the second semiconductor pillar; a first gate conductor layer around the first gate insulating layer; a second gate conductor layer around the second gate insulating layer; a first impurity region connected to a lower portion of the first semiconductor pillar; a second impurity region connected to a lower portion of the second semiconductor pillar; a third impurity region connected to a top portion of the first semiconductor pillar; and a fourth impurity region connected to a top portion of the second semiconductor pillar, and
the pillar-shaped semiconductor device has: a first SGT in which the first semiconductor pillar between the first impurity region and the third impurity region is a channel; and a second SGT in which the second semiconductor pillar between the second impurity region and the fourth impurity region is a channel,
wherein the method comprises:
a step of forming, on a surface of the substrate, the first impurity region and the second impurity region each containing a donor or acceptor impurity;
a step of forming a semiconductor pillar layer, which will serve as the first and second semiconductor pillars, on the first impurity region and the second impurity region to cover an entire surface, and forming the third impurity region and the fourth impurity region on the semiconductor pillar layer;
a step of forming a first hard mask layer on the third impurity region and the fourth impurity region to cover an entire surface;
a step of forming a first support layer in a band shape in plan view on the first hard mask layer on the first semiconductor pillar region, and forming a second support layer in a rectangular shape in plan view on the first hard mask layer on the second semiconductor pillar region;
a step of forming a second hard mask layer to cover an entire surface;
a step of anisotropically etching the second hard mask layer to form first sidewalls composed of the second hard mask layer and located on side walls of the first and second support layers;
a step of forming a first insulating layer to cover an entire surface;
a step of polishing the first insulating layer until surfaces of top portions of the first and second support layers are exposed;
a step of forming a third hard mask layer to cover an entire surface;
a step of forming a third support layer on the third hard mask layer in the first semiconductor pillar region such that the third support layer has a band shape so as to perpendicularly cross the first support layer in plan view, and forming a fourth support layer on the third hard mask layer in the second semiconductor pillar region such that the fourth support layer has a rectangular opening inside so as to surround the first sidewall in plan view;
a step of forming a fourth hard mask layer to cover an entire surface;
a step of anisotropically etching the fourth hard mask layer to form second sidewalls composed of the fourth hard mask layer and located on side walls of the third and fourth support layer;
a step of forming, by photolithography, a photoresist above the first semiconductor pillar region so as to cover the second sidewall in a region for forming the CSGT and forming the photoresist above the second semiconductor pillar region so as to cover the second sidewall in a region for forming the ESGT;
a step of anisotropically etching the exposed second sidewalls away and stripping the photoresist;
a step of removing the third and fourth support layers and sequentially anisotropically etching the third hard mask layer and the first sidewalls by using the remaining second sidewalls as a mask to remove the first insulating layer, the first support layer, and the second support layer;
a step of sequentially anisotropically etching the first hard mask layer, the third impurity region and the fourth impurity region, the semiconductor pillar layer, and the first impurity region and the second impurity region by using the remaining first sidewalls as a mask to form the first semiconductor pillar and the second semiconductor pillar;
a step of forming the first gate insulating layer around the first semiconductor pillar, and forming the second gate insulating layer around the second semiconductor pillar; and
a step of forming the first gate conductor layer around the first gate insulating layer, and forming the second gate conductor layer around the second gate insulating layer.

The production method preferably includes:
after forming the third hard mask layer to cover the entire surface,
a step of forming the third support layer such that the third support layer has a band shape so as to perpendicularly cross the first support layer in plan view, and a step of forming the fourth support layer such that the fourth support layer has a rectangular opening inside so as to surround the first sidewall and forming a fifth support layer inside the first sidewall such that the fifth support layer has a rectangular shape in plan view;
a step of forming the fourth hard mask layer to cover an entire surface so that a space between the fourth support layer and the fifth support layer in the second semiconductor pillar region is embedded in the fourth hard mask layer; and
a step of anisotropically etching the fourth hard mask layer to form the second sidewall composed of the fourth hard mask layer and located on a side wall of the third support layer, and removing the fourth hard mask layer on the fourth and fifth support layers so that the space between the fourth support layer and the fifth support layer is filled with the fourth hard mask layer.

The production method preferably includes:
a step of forming the second support layer in a rectangular frame shape in plan view;
a step of forming the second hard mask layer to cover an entire surface so that a space inside an inner frame of the second support layer is embedded in the second hard mask layer;
a step of anisotropically etching the second hard mask layer to form the first sidewall composed of the second hard mask layer and located on a side wall of the first support layer and to fill the space inside the inner frame of the second support layer with the second hard mask layer;
a step of forming the first insulating layer to cover an entire surface;
a step of polishing the first insulating layer until a surface of a top portion of the second support layer is exposed;
a step of forming the third hard mask layer to cover an entire surface;
a step of forming the fourth support layer such that edges of the fourth support layer are positioned above the filled second hard mask layer in vertical view;
a step of forming the fourth hard mask layer to cover an entire surface; and
a step of anisotropically etching the fourth hard mask layer to form the second sidewall composed of the fourth hard mask layer and located on a side wall of the fourth support layer.

The production method preferably includes:
after forming the third hard mask layer to cover the entire surface,
a step of forming the fourth support layer such that the fourth support layer has a rectangular opening such that at least part of the remaining first sidewall is exposed in plan view;
a step of forming the fourth hard mask layer to cover an entire surface; and
a step of anisotropically etching the fourth hard mask layer to form the second sidewall composed of the fourth hard mask layer and located on a side wall of the third support layer and to fill the opening of the fourth support layer with the fourth hard mask layer.

### BRIEF DESCRIPTION OF THE DRAWINGS

FIGS. 1ACA, 1ACB, and 1ACC are a plan view and cross-sectional views for describing a method for producing a pillar-shaped semiconductor device having CSGTs and ESGTs according to a first embodiment.

FIGS. 1AEA, 1AEB, and 1AEC are a plan view and cross-sectional views for describing the method for producing a pillar-shaped semiconductor device having CSGTs and ESGTs according to the first embodiment.

FIGS. 1BCA, 1BCB, and 1BCC are a plan view and cross-sectional views for describing the method for producing the pillar-shaped semiconductor device having CSGTs and ESGTs according to the first embodiment.

FIGS. 1BEA, 1BEB, and 1BEC are a plan view and cross-sectional views for describing the method for producing the pillar-shaped semiconductor device having CSGTs and ESGTs according to the first embodiment.

FIGS. 1CCA, 1CCB, and 1CCC are a plan view and cross-sectional views for describing the method for producing the pillar-shaped semiconductor device having CSGTs and ESGTs according to the first embodiment.

FIGS. 1CEA, 1CEB, and 1CEC are a plan view and cross-sectional views for describing the method for producing the pillar-shaped semiconductor device having CSGTs and ESGTs according to the first embodiment.

FIGS. 1DCA, 1DCB, and 1DCC are a plan view and cross-sectional views for describing the method for producing the pillar-shaped semiconductor device having CSGTs and ESGTs according to the first embodiment.

FIGS. 1DEA, 1DEB, and 1DEC are a plan view and cross-sectional views for describing the method for producing the pillar-shaped semiconductor device having CSGTs and ESGTs according to the first embodiment.

FIGS. 1ECA, 1ECB, and 1ECC are a plan view and cross-sectional views for describing the method for producing the pillar-shaped semiconductor device having CSGTs and ESGTs according to the first embodiment.

FIGS. 1EEA, 1EEB, and 1EEC are a plan view and cross-sectional views for describing the method for producing the pillar-shaped semiconductor device having CSGTs and ESGTs according to the first embodiment.

FIGS. 1FCA, 1FCB, and 1FCC are a plan view and cross-sectional views for describing the method for producing the pillar-shaped semiconductor device having CSGTs and ESGTs according to the first embodiment.

FIGS. 1FEA, 1FEB, and 1FEC are a plan view and cross-sectional views for describing the method for producing the pillar-shaped semiconductor device having CSGTs and ESGTs according to the first embodiment.

FIGS. 1GCA, 1GCB, and 1GCC are a plan view and cross-sectional views for describing the method for producing the pillar-shaped semiconductor device having CSGTs and ESGTs according to the first embodiment.

FIGS. 1GEA, 1GEB, and 1GEC are a plan view and cross-sectional views for describing the method for producing the pillar-shaped semiconductor device having CSGTs and ESGTs according to the first embodiment.

FIGS. 1HCA, 1HCB, and 1HCC are a plan view and cross-sectional views for describing the method for producing the pillar-shaped semiconductor device having CSGTs and ESGTs according to the first embodiment.

FIGS. 1HEA, 1HEB, and 1HEC are a plan view and cross-sectional views for describing the method for producing the pillar-shaped semiconductor device having CSGTs and ESGTs according to the first embodiment.

FIGS. 1JCA, 1JCB, and 1JCC are a plan view and cross-sectional views for describing the method for producing the pillar-shaped semiconductor device having CSGTs and ESGTs according to the first embodiment.

FIGS. 1JEA, 1JEB, and 1JEC are a plan view and cross-sectional views for describing the method for producing the pillar-shaped semiconductor device having CSGTs and ESGTs according to the first embodiment.

FIGS. 1KCA, 1KCB, and 1KCC are a plan view and cross-sectional views for describing the method for producing the pillar-shaped semiconductor device having CSGTs and ESGTs according to the first embodiment.

FIGS. 1KEA, 1KEB, and 1KEC are a plan view and cross-sectional views for describing the method for producing the pillar-shaped semiconductor device having CSGTs and ESGTs according to the first embodiment.

FIGS. 1LCA, 1LCB, and 1LCC are a plan view and cross-sectional views for describing the method for producing the pillar-shaped semiconductor device having CSGTs and ESGTs according to the first embodiment.

FIGS. 1LEA, 1LEB, and 1LEC are a plan view and cross-sectional views for describing the method for producing the pillar-shaped semiconductor device having CSGTs and ESGTs according to the first embodiment.

FIGS. 1MCA, 1MCB, and 1MCC are a plan view and cross-sectional views for describing the method for producing the pillar-shaped semiconductor device having CSGTs and ESGTs according to the first embodiment.

FIGS. 1MEA, 1MEB, and 1MEC are a plan view and cross-sectional views for describing the method for producing the pillar-shaped semiconductor device having CSGTs and ESGTs according to the first embodiment.

FIGS. 1NCA, 1NCB, and 1NCC are a plan view and cross-sectional views for describing the method for producing the pillar-shaped semiconductor device having CSGTs and ESGTs according to the first embodiment.

FIGS. 1NEA, 1NEB, and 1NEC are a plan view and cross-sectional views for describing the method for producing the pillar-shaped semiconductor device having CSGTs and ESGTs according to the first embodiment.

FIGS. 1PCA, 1PCB, and 1PCC are a plan view and cross-sectional views for describing the method for producing the pillar-shaped semiconductor device having CSGTs and ESGTs according to the first embodiment.

FIGS. 1PEA, 1PEB, and 1PEC are a plan view and cross-sectional views for describing the method for producing the pillar-shaped semiconductor device having CSGTs and ESGTs according to the first embodiment.

FIGS. 2AEA, 2AEB, and 2AEC are a plan view and cross-sectional views for describing a method for producing a pillar-shaped semiconductor device having ESGTs according to a second embodiment of the present invention.

FIGS. 2BEA, 2BEB, and 2BEC are a plan view and cross-sectional views for describing the method for producing the pillar-shaped semiconductor device having ESGTs according to the second embodiment of the present invention.

FIGS. 3AEA, 3AEB, and 3AEC are a plan view and cross-sectional views for describing a method for producing a pillar-shaped semiconductor device having an ESGT according to a third embodiment of the present invention.

FIGS. 3BEA, 3BEB, and 3BEC are a plan view and cross-sectional views for describing the method for producing the pillar-shaped semiconductor device having an ESGT according to the third embodiment of the present invention.

FIGS. 3CEA, 3CEB, and 3CEC are a plan view and cross-sectional views for describing the method for producing the pillar-shaped semiconductor device having an ESGT according to the third embodiment of the present invention.

FIGS. 3DEA, 3DEB, and 3DEC are a plan view and cross-sectional views for describing the method for producing the pillar-shaped semiconductor device having an ESGT according to the third embodiment of the present invention.

FIGS. 3EEA, 3EEB, and 3EEC are a plan view and cross-sectional views for describing the method for producing the pillar-shaped semiconductor device having an ESGT according to the third embodiment of the present invention.

FIGS. 4AEA, 4AEB, and 4AEC are a plan view and cross-sectional views for describing a method for producing a pillar-shaped semiconductor device having an ESGT according to a fourth embodiment of the present invention.

FIGS. 4BEA, 4BEB, and 4BEC are a plan view and cross-sectional views for describing the method for producing the pillar-shaped semiconductor device having an ESGT according to the fourth embodiment of the present invention.

FIGS. 4CEA, 4CEB, and 4CEC are a plan view and cross-sectional views for describing the method for producing the pillar-shaped semiconductor device having an ESGT according to the fourth embodiment of the present invention.

FIGS. 5A and 5B are schematic views of a CSGT and an ESGT according to examples of the related art.

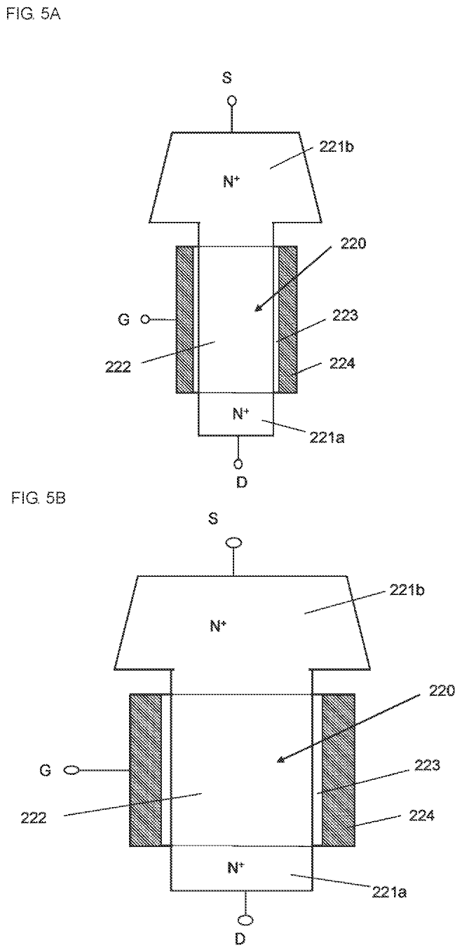

FIG. 6 is a circuit diagram of an SRAM cell including SGTs according to an example of the related art.

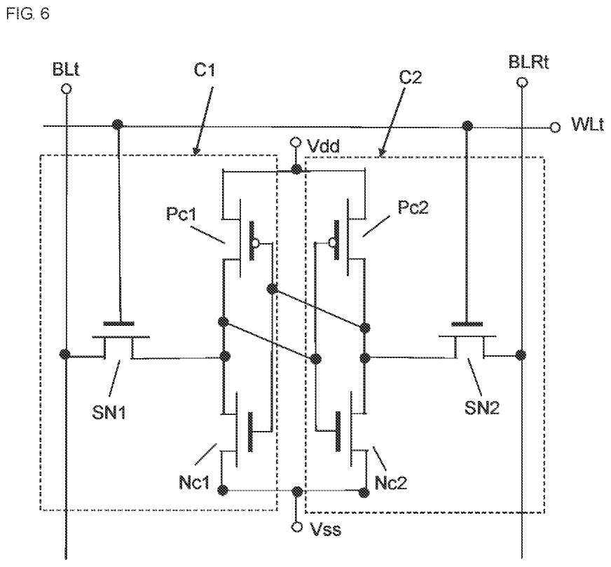

### DESCRIPTION OF THE PREFERRED EMBODIMENTS

A method for producing a pillar-shaped semiconductor device according to embodiments of the present invention will be described below with reference to the drawings.

### First Embodiment

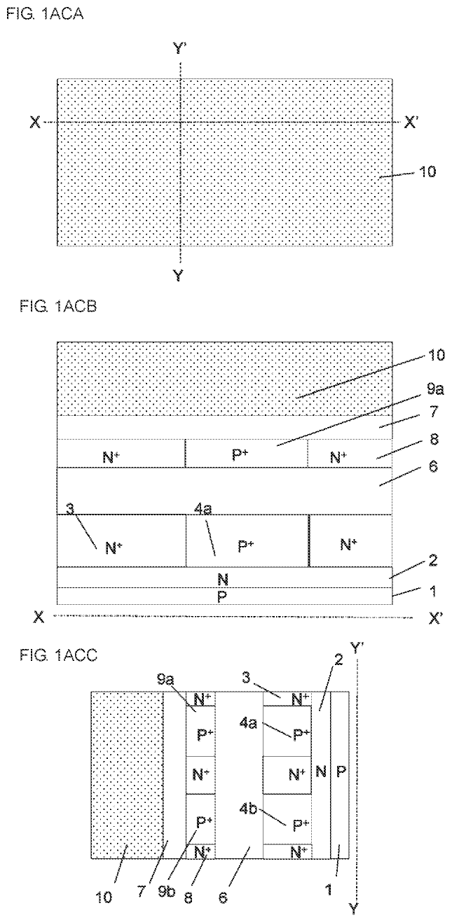

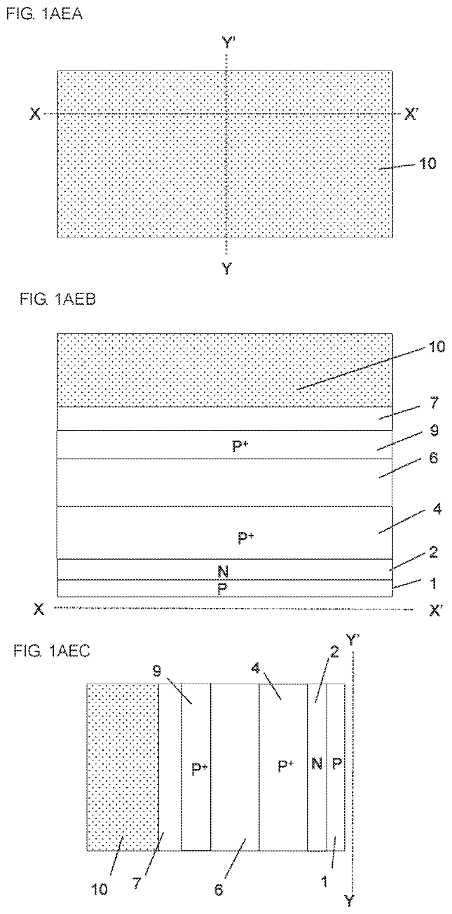

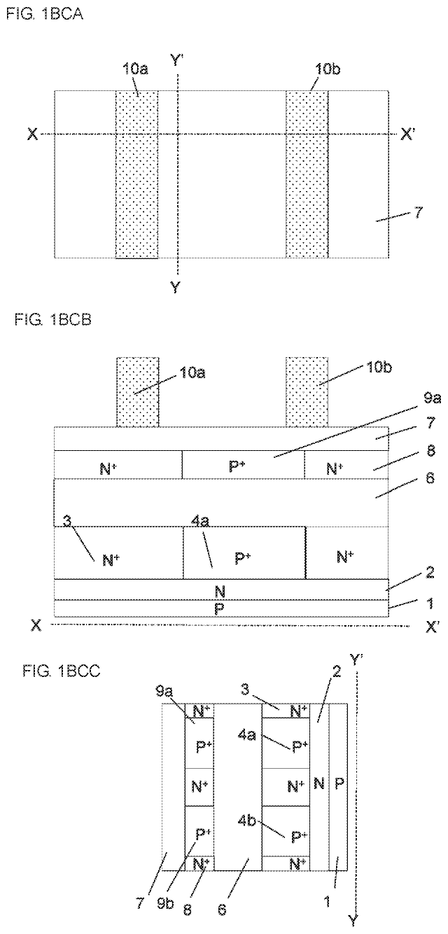

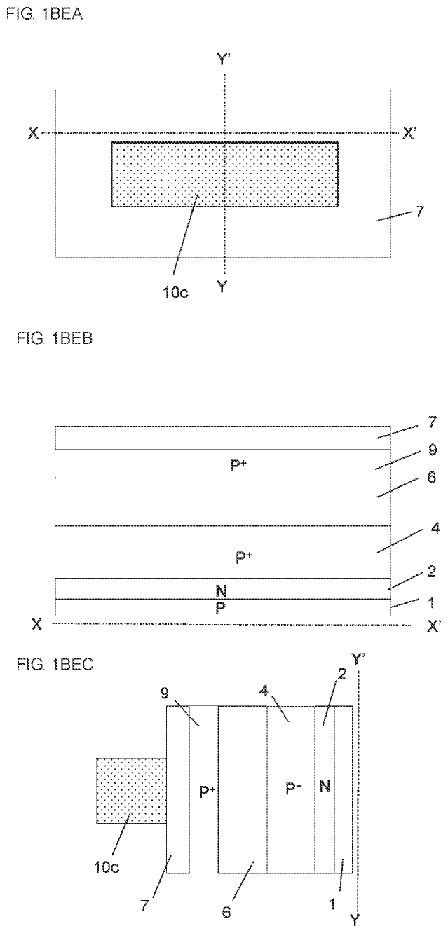

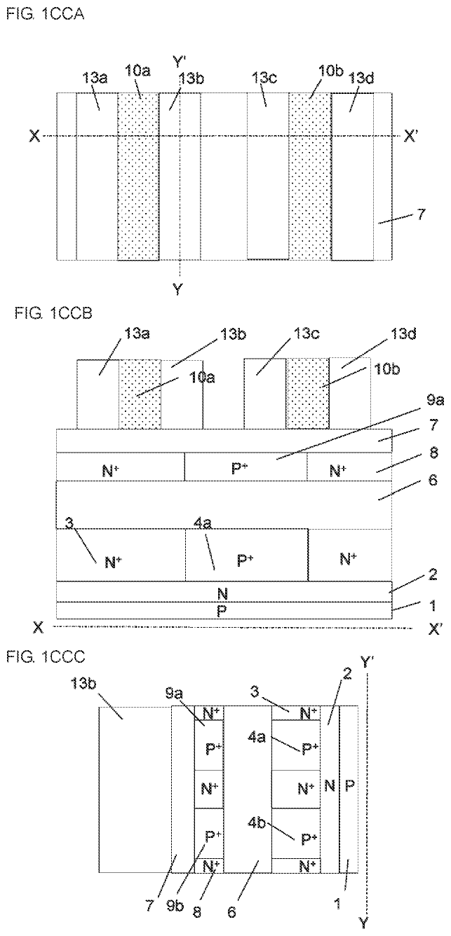

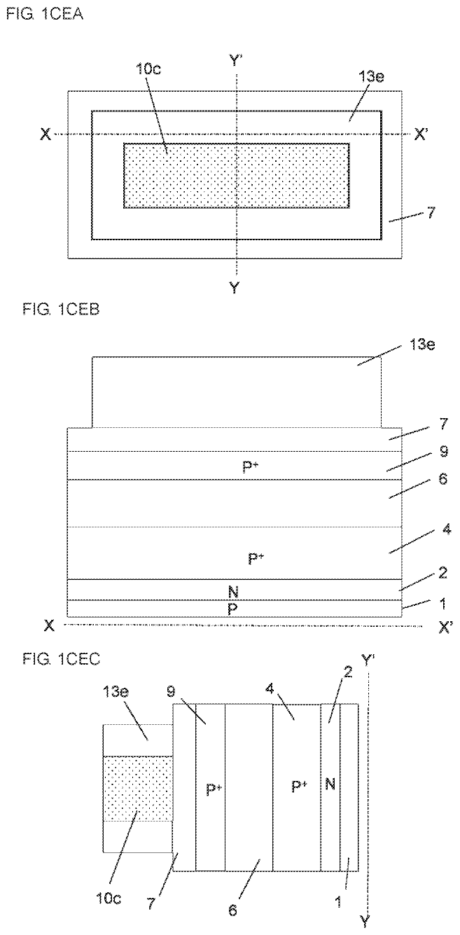

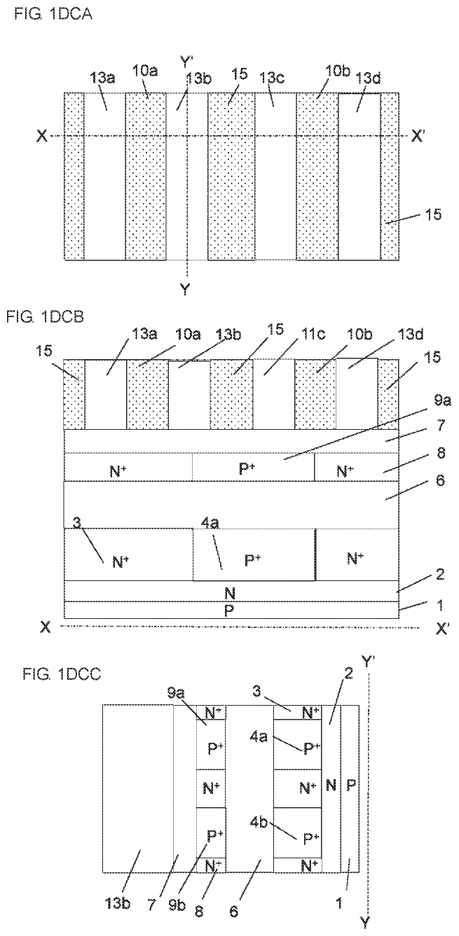

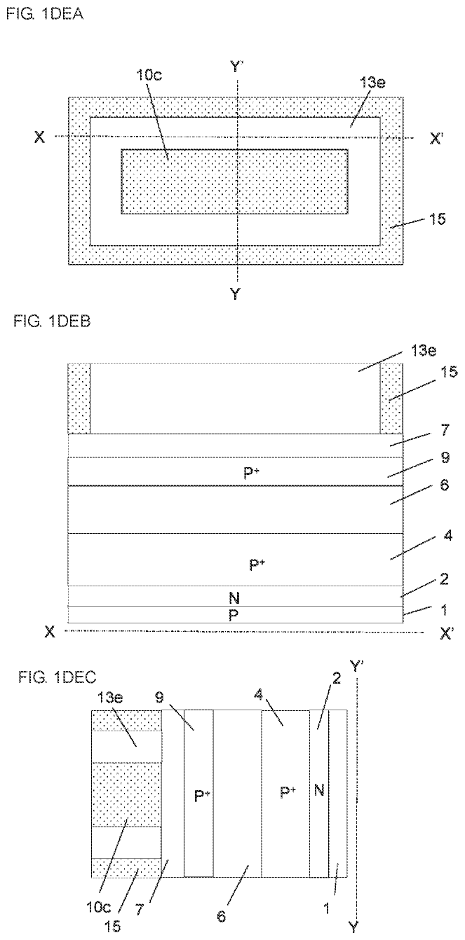

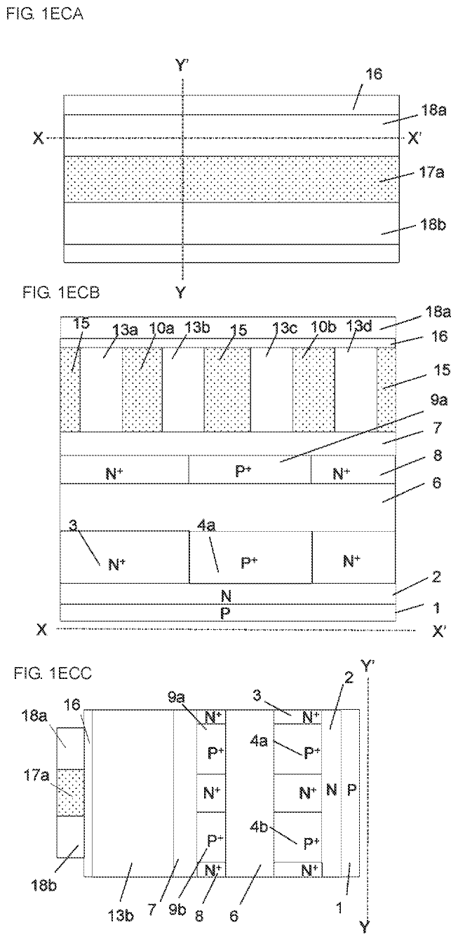

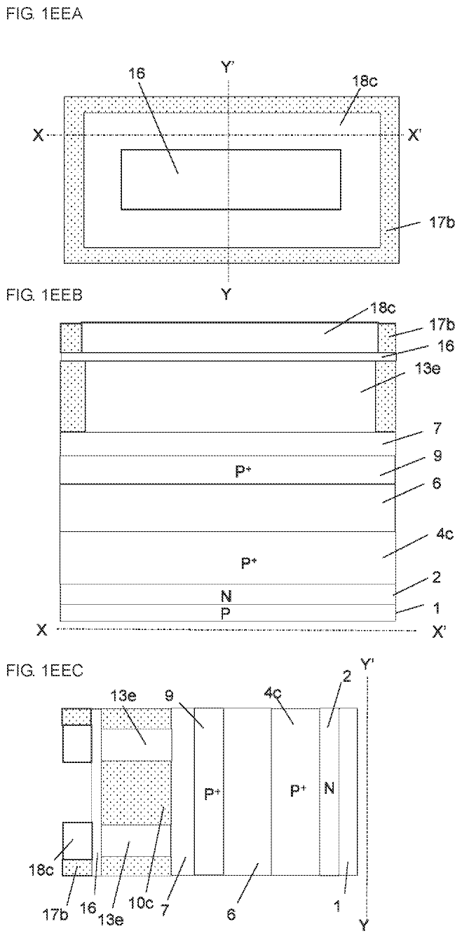

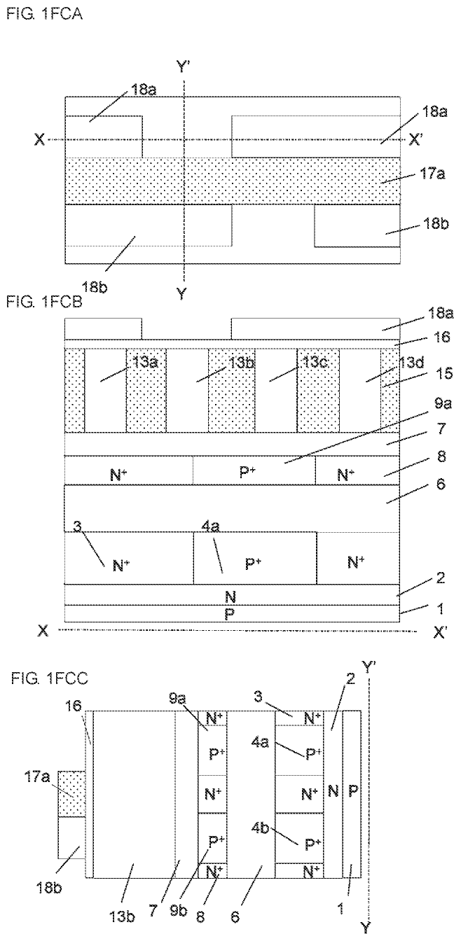

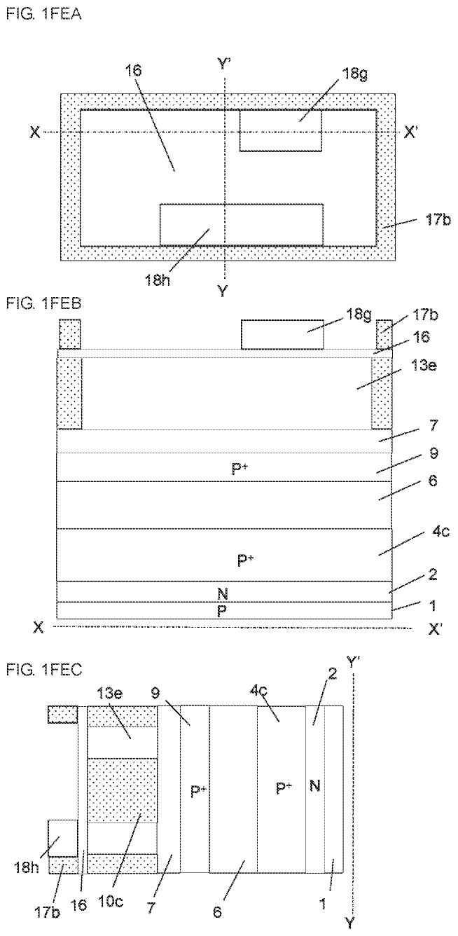

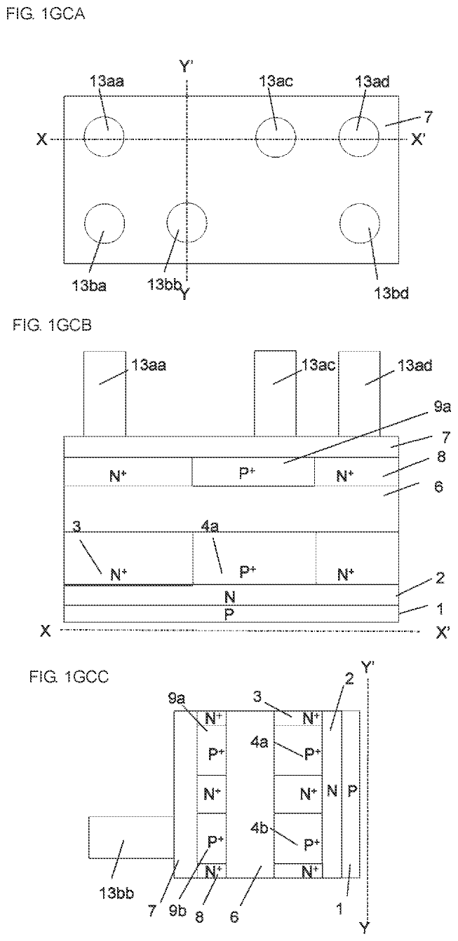

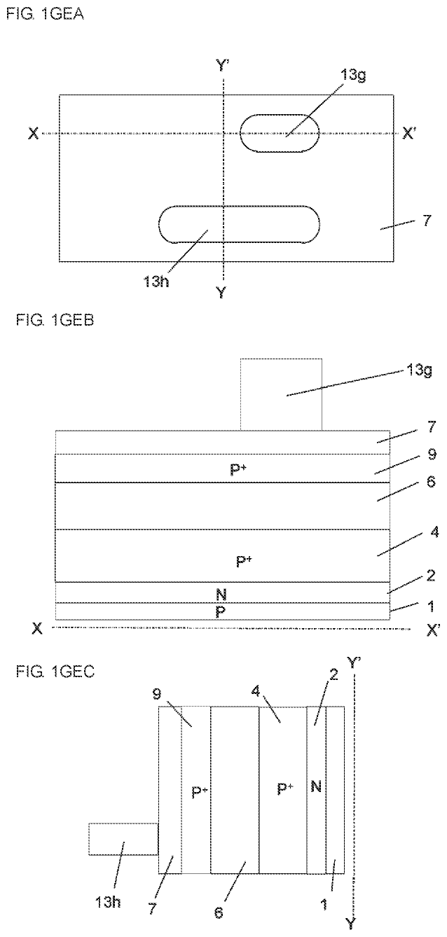

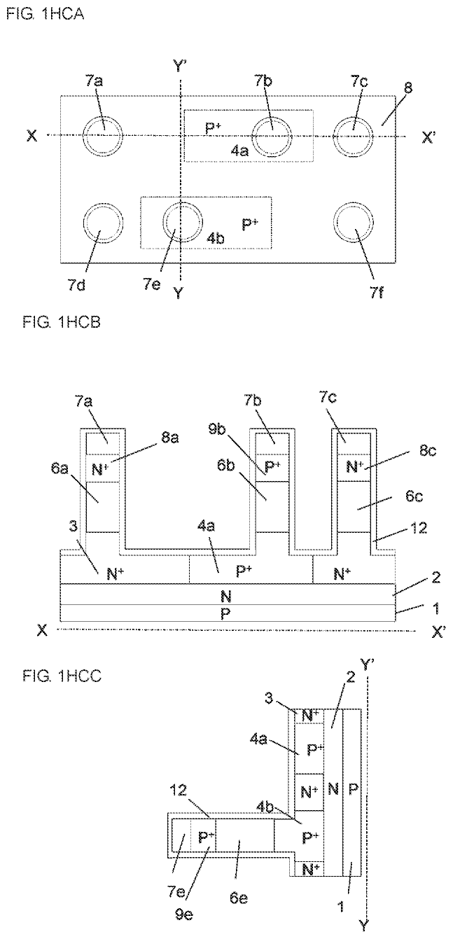

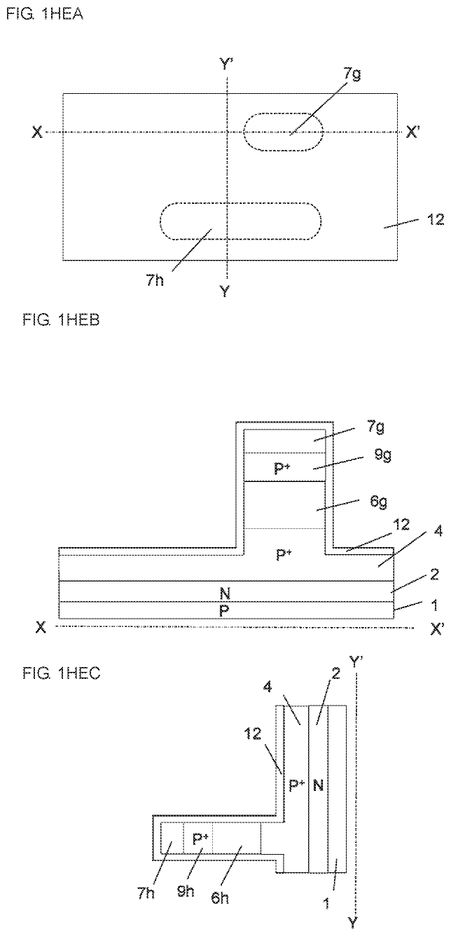

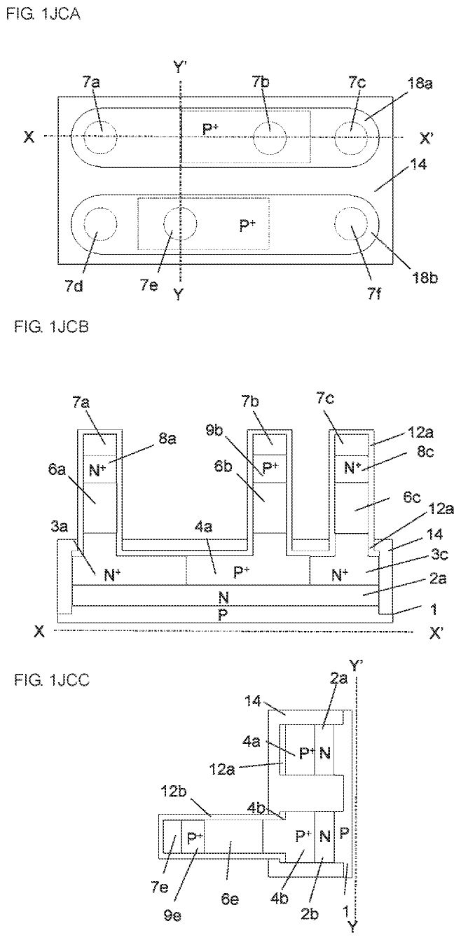

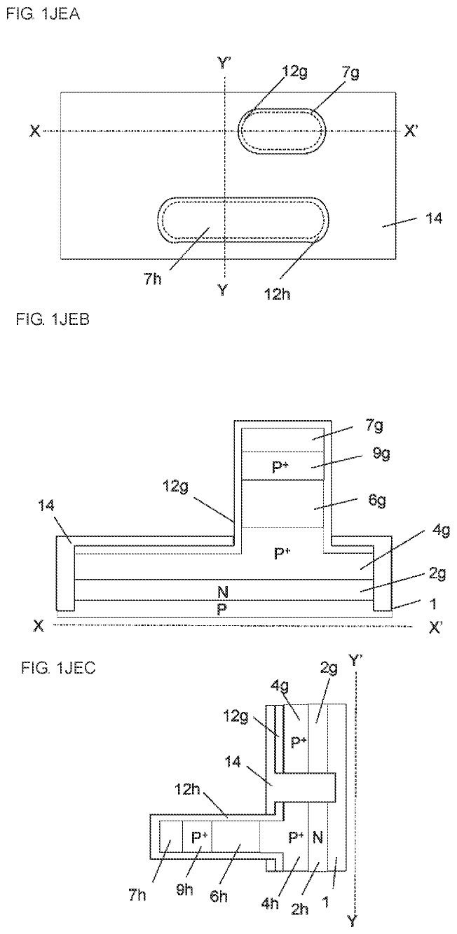

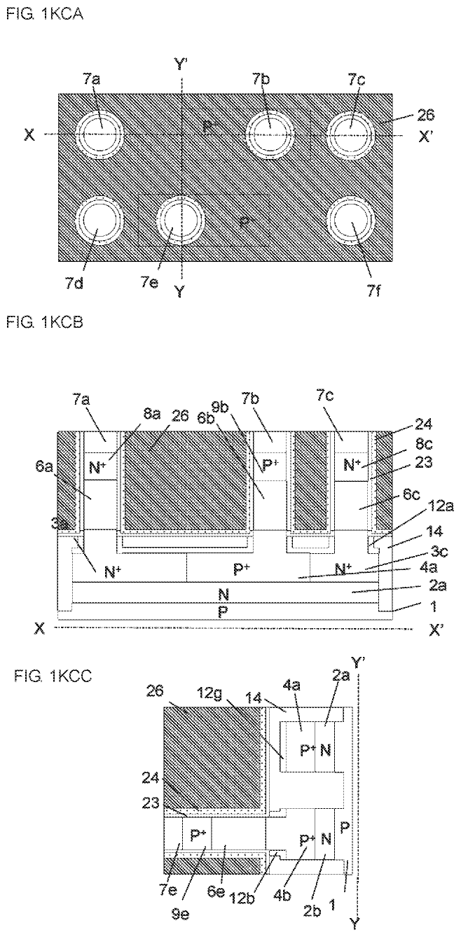

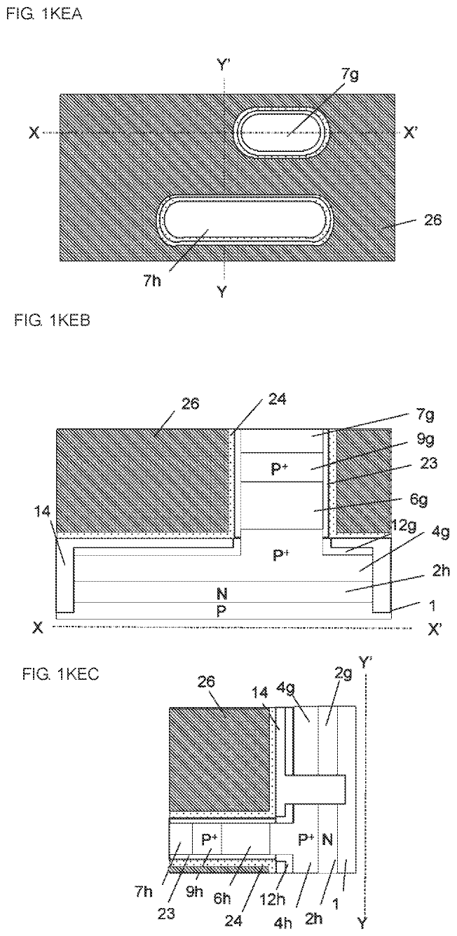

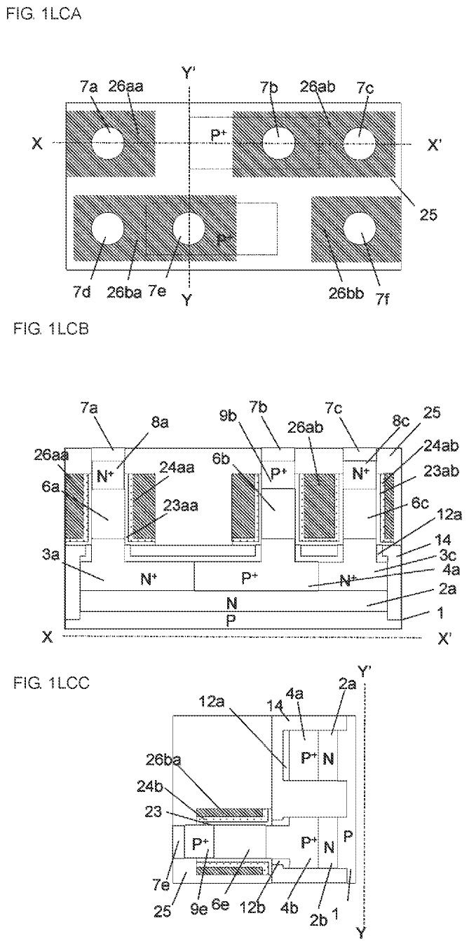

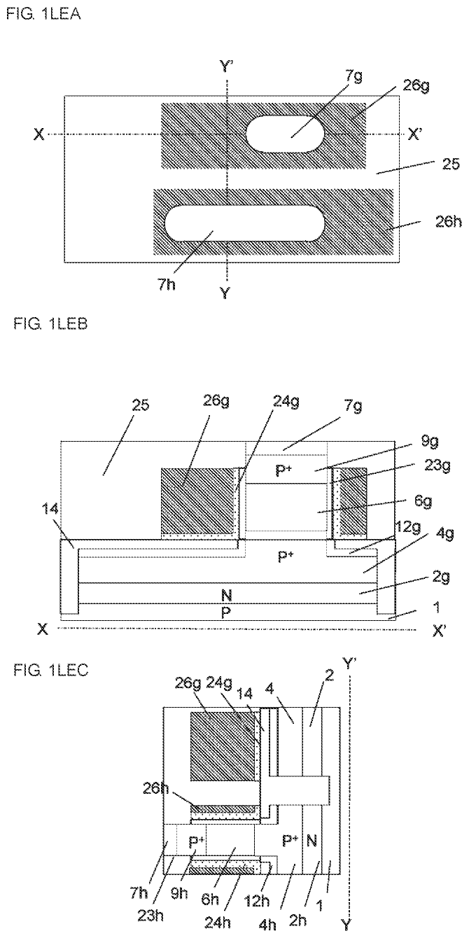

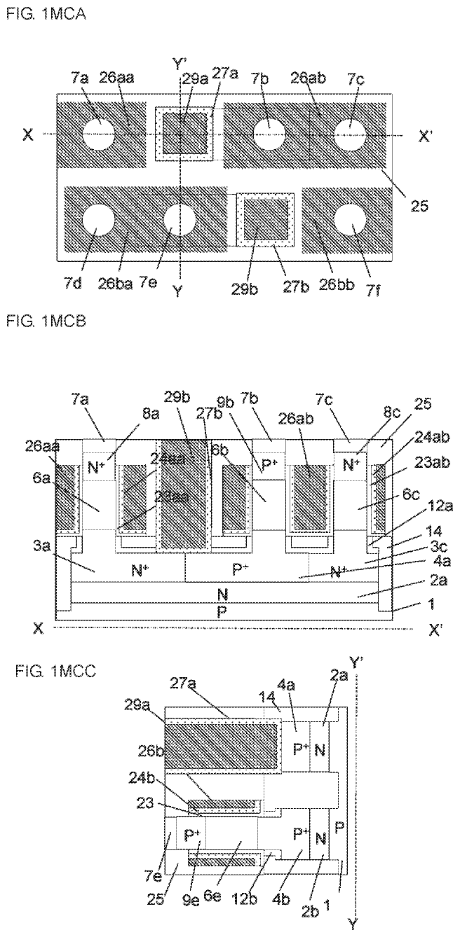

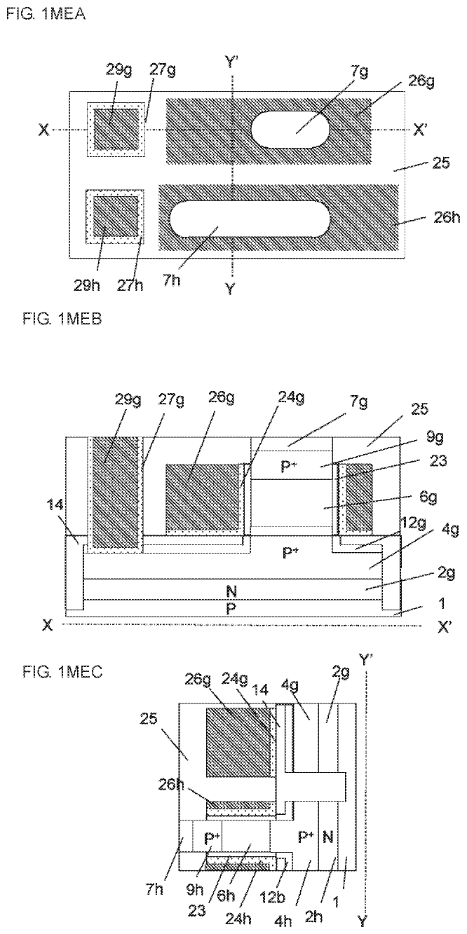

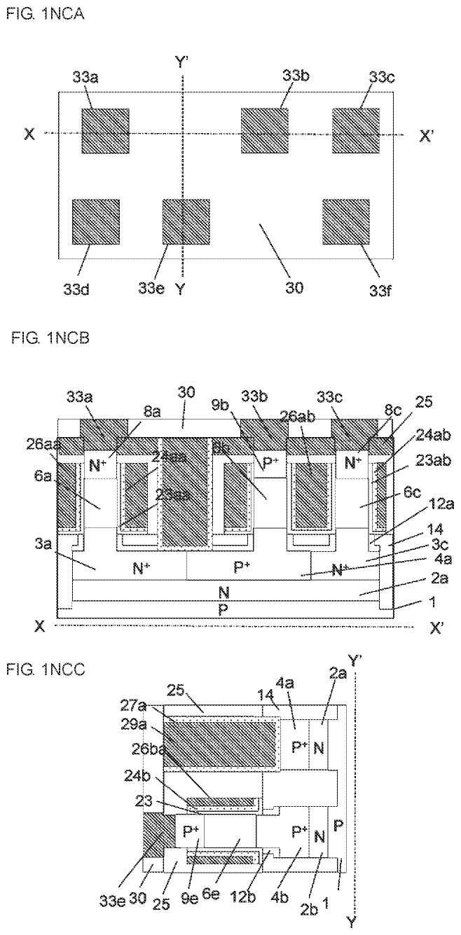

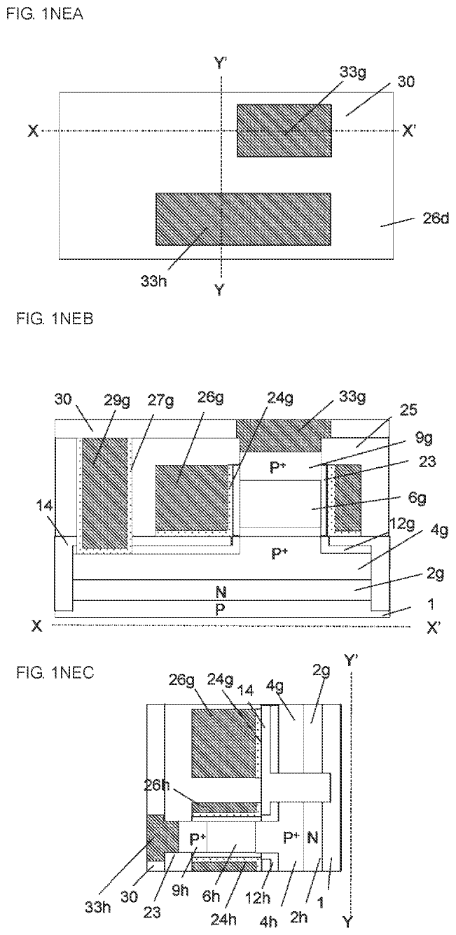

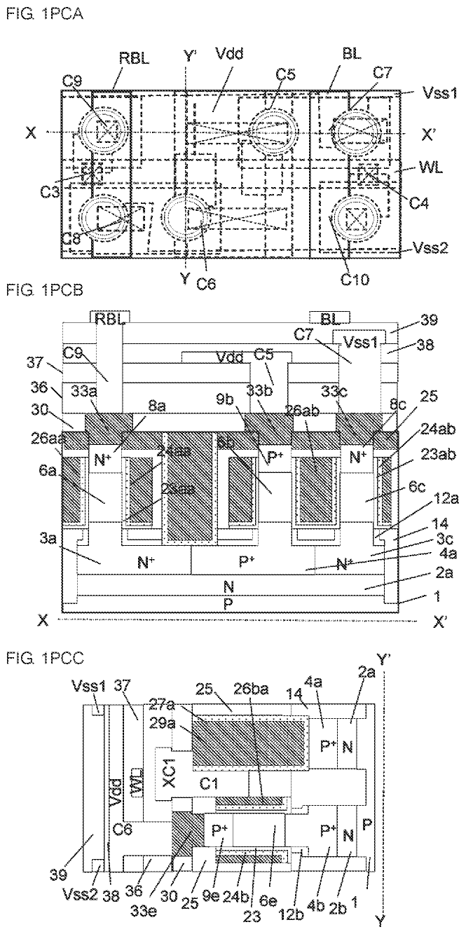

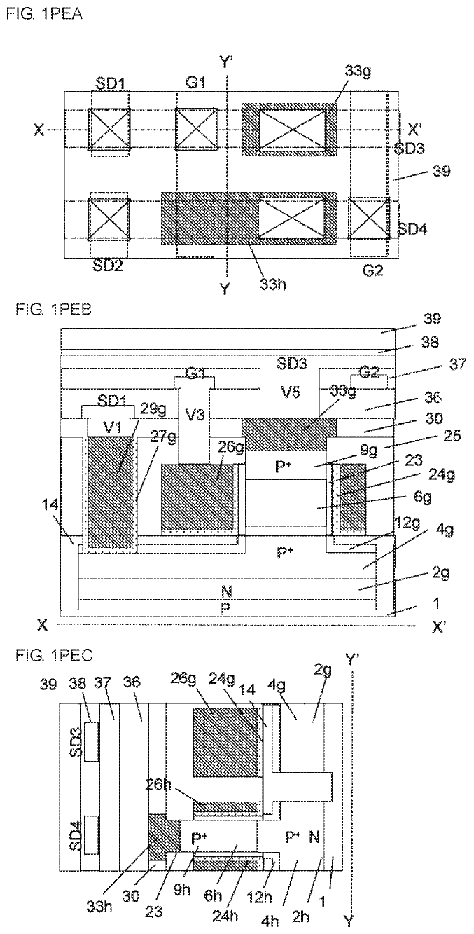

A method for producing CSGTs used in SRAM cells and ESGTs of PMOS used in logic circuits as examples having SGTs according to a first embodiment of the present invention will be described below with reference to FIGS. 1ACA to 1PEC. FIGS. 1ACA, 1BCA, 1CCA, 1DCA, 1ECA, 1FCA, 1GCA, 1HCA, 1JCA, 1KCA, 1LCA, 1MCA, 1NCA, and 1PCA are plan views of an SRAM cell. FIGS. 1ACB, 1BCB, 1CCB, 1DCB, 1ECB, 1FCB, 1GCB, 1HCB, 1JCB, 1KCB, 1LCB, 1MCB, 1NCB, and 1PCB are cross-sectional views taken along line X-X′ in FIGS. 1ACA, 1BCA, 1CCA, 1DCA, 1ECA, 1FCA, 1GCA, 1HCA, 1JCA, 1KCA, 1LCA, 1MCA, 1NCA, and 1PCA. FIGS. 1ACC, 1BCC, 1CCC, 1DCC, 1ECC, 1FCC, 1GCC, 1HCC, 1JCC, 1KCC, 1LCC, 1MCC, 1NCC, and 1PCC are cross-sectional views taken along line Y-Y′ in FIGS. 1ACA, 1BCA, 1CCA, 1DCA, 1ECA, 1FCA, 1GCA, 1HCA, 1JCA, 1KCA, 1LCA, 1MCA, 1NCA, and 1PCA. FIGS. 1AEA, 1BEA, 1CEA, 1DEA, 1EEA, 1FEA, 1GEA, 1HEA, 1JEA, 1KEA, 1LEA, 1MEA, 1NEA, and 1PEA are plan views of PMOS. FIGS. 1AEB, 1BEB, 1CEB, 1DEB, 1EEB, 1FEB, 1GEB, 1HEB, 1JEB, 1KEB, 1LEB, 1MEB, 1NEB, and 1PEB are cross-sectional views taken along line X-X′ in FIGS. 1AEA, 1BEA, 1CEA, 1DEA, 1EEA, 1FEA, 1GEA, 1HEA, 1JEA, 1KEA, 1LEA, 1MEA, 1NEA, and 1PEA. FIGS. 1AEC, 1BEC, 1CEC, 1DEC, 1EEC, 1FEC, 1GEC, 1HEC, 1JEC, 1KEC, 1LEC, 1MEC, 1NEC, and 1PEC are cross-sectional views taken along line Y-Y′ in FIGS. 1AEA, 1BEA, 1CEA, 1DEA, 1EEA, 1FEA, 1GEA, 1HEA, 1JEA, 1KEA, 1LEA, 1MEA, 1NEA, and 1PEA.

An n-layer 2 (an example of the “substrate” in Claims) is formed on a p-layer 1 (an example of the “substrate” in Claims) by epitaxial crystal growth to form a substrate. As illustrated in FIGS. 1ACA to 1ACC, an n⁺-layer 3 (an example of the “first impurity region” in Claims), and p⁺-layers 4a and 4b (examples of the “first impurity region” in Claims) are formed at desired positions on the surface layer of the n-layer 2, namely, the surface of the substrate, by epitaxial crystal growth or ion implantation, and an i-layer 6 (an example of the “semiconductor pillar” in Claims), an n⁺-layer 8 (an example of the “third impurity region” in Claims), and p⁺-layers 9a and 9b (examples of the “third impurity region” in Claims) are formed at desired positions by epitaxial crystal growth. Next, a hard mask layer 7 (an example of the “first hard mask layer” in Claims) made of, for example, SiN, and a support layer 10 composed of, for example, a SiO₂ layer are sequentially deposited. Similarly, as illustrated in FIGS. 1AEA to 1AEC, a p⁺-layer 4 (an example of the “second impurity region” in Claims) is formed at a desired position on the surface layer of the substrate by epitaxial crystal growth or ion implantation, and an i-layer 6 (an example of the “semiconductor pillar” in Claims) and a pt-layer 9 (an example of the “fourth impurity region” in Claims) are formed by epitaxial crystal growth. Next, a hard mask layer 7 (an example of the “first hard mask layer” in Claims) made of, for example, SiN, and a support layer 10 composed of, for example, a SiO₂ layer are sequentially deposited.

Next, as illustrated in FIGS. 1BCA to 1BCC, the SiO₂ support layer 10 is etched by using, as a mask, a band-shaped resist layer (not shown) formed by lithography and extending in the Y-direction in plan view to form band-shaped SiO₂ support layers 10a and 10b (examples of the “first support layer” in Claims) extending in the Y-direction in plan view. Similarly, as illustrated in FIGS. 1BEA to 1BEC, the SiO₂ support layer 10 is etched by using, as a mask, a resist layer (not shown) having a rectangular shape in plan view and formed by lithography to form a SiO₂ support layer 10c (an example of the “second support layer” in Claims) having a rectangular shape in plan view.

Next, the entire surface is covered with a hard mask layer 13 (not shown) (an example of the “second hard mask layer” in Claims) made of amorphous Si according to, for example, chemical vapor deposition (CVD), and the amorphous Si-hard mask layer 13 is anisotropically etched to form sidewalls 13a, 13b, 13c, 13d, and 13e (examples of the “first sidewall” in Claims) made of amorphous Si and located on the side walls of the band-shaped SiO₂ support layers 10a and 10b and the rectangular SiO₂ support layer 10c, as illustrated in FIGS. 1CCA to 1CCE and FIGS. 1CEA to 1CEE.

Next, the entire surface is covered with an insulating layer 15 (an example of the “first insulating layer” in Claims) made of SiO₂ according to, for example, CVD, and the insulating layer 15 is polished until the top portions of the sidewalls are exposed, as illustrated in FIGS. 1DCA to 1DCE and FIGS. 1DEA to 1DEE.

Next, the entire surface is covered with a hard mask layer 16 (an example of the “third hard mask layer” in Claims) made of SiN and a support layer 17 made of SiO₂ according to, for example, CVD. As illustrated in FIGS. 1ECA to 1ECC, the SiO₂ support layer 17 is etched by using, as a mask, a band-shaped resist layer (not shown) formed by lithography and extending in the X-direction in plan view to form a band-shaped SiO₂ support layer 17a (an example of the “third support layer” in Claims). Next, the entire surface is covered with a hard mask layer 18 (not shown) (an example of the “fourth hard mask layer” in Claims) made of amorphous Si according to, for example, CVD, and the amorphous Si-hard mask layer 18 is anisotropically etched away to form sidewalls 18a and 18b (examples of the “second sidewall” in Claims) made of amorphous Si and located on the side walls of the band-shaped SiO₂ support layer 17a. Similarly, as illustrated in FIGS. 1EEA to 1EEC, the SiO₂ support layer 17 is etched by using, as a mask, a resist layer (not shown) formed by lithography and having a rectangular opening such that the sidewall 13e in the lower layer is exposed through the hard mask layer 16 in plan view to form a SiO₂ support layer 17b (an example of the “fourth support layer” in Claims) having a rectangular frame shape in plan view. Next, the entire surface is covered with an amorphous Si-hard mask layer 18 (not shown), and the amorphous Si-hard mask layer 18 is anisotropically etched away to form a sidewall 18c (an example of the “second sidewall” in Claims) made of amorphous Si and located on the side wall of the SiO₂ support layer 17b having a rectangular frame shape.

Next, as illustrated in FIGS. 1FCA to 1FCC and FIGS. 1FEA to 1FEC, the sidewalls 18a, 18b, and 18c, which are formed by lithography, in predetermined regions each forming a semiconductor pillar are covered with a resist layer (not shown). The sidewalls 18a, 18b, and 18c are anisotropically etched away, and the resist layer is stripped.

Next, as illustrated in FIGS. 1GCA to 1GCC and FIGS. 1GEA to 1GEC, the support layers 17a and 17b are removed, and the hard mask layer 16 and the sidewalls 13a, 13b, 13c, 13d, and 13e are sequentially anisotropically etched by using the sidewalls 18a, 18b, and 18c as a mask to form sidewalls 13aa, 13ac, 13ad, 13ba, 13bb, 13bd, 13g, and 13h and remove the SiO₂ support layers 10a, 10b, and 10c and the SiO₂ insulating layer 15.

Next, the hard mask layer 7, the n⁺-layer 8, the p⁺-layers 9a, 9b, and 9, and the i-layer 6 are anisotropically etched by using the sidewalls 13aa, 13ac, 13ad, 13ba, 13bb, 13bd, 13g, and 13h as masks. Next, an n⁺-layer 3 and the p⁺-layers 4a, 4b, and 4 are anisotropically etched such that the n⁺-layer 3 and the p⁺-layers 4a, 4b, and 4 partially remain to form semiconductor pillars 6a, 6b, 6c, 6d, 6e, 6f, 6g, and 6h on the n⁺-layer 3 and the p⁺-layers 4a, 4b, and 4, and as illustrated in FIGS. 1HCA to 1HCC and FIGS. 1HEA to 1HEC, the entire surface is covered with a semiconductor pillar protective film 12 made of, for example, SiN according to, for example, FCVD.

Next, the semiconductor pillar protective film 12, the n⁺-layer 3 and the p⁺-layers 4a, 4b, and 4, the n-layer 2, and the p-layer substrate 1 are etched to form, as illustrated in FIGS. 1JCA to 1JCC and FIGS. 1JEA to 1JEC, a semiconductor pillar base 18a including an upper portion of the p-layer substrate 1, an n-layer 2a, n⁺-layers 3a and 3c, and a p⁺-layer 4a and form a semiconductor pillar base 18b including an n-layer 2b, n⁺-layers 3d and 3f, and the p⁺-layer 4b, a semiconductor pillar base 18c including an n-layer 2c and the p⁺-layer 4g, and a semiconductor pillar base 18d including an n-layer 2d and the p⁺-layer 4h. The entire surface is covered with an inter-element insulating layer 14 made of SiO₂ and formed by ALD, and the entire surface is polished by CMP such that the upper surface of the inter-element insulating layer 14 is flush with the upper surface of the semiconductor protective layer 12 on mask semiconductor layers 7a, 7b, 7c, 7d, 7e, 7f, 7g, and 7h. Next, the inter-element insulating layer 14 is subjected to recess etching such that the upper surface of the inter-element insulating layer 14 is lower than the lower surfaces of the semiconductor pillars 6a, 6b, 6c, 6d, 6e, 6f, 6g, and 6h.

Next, the semiconductor pillar protective film 12 exposed on the surface is removed, and the entire surface is covered, by ALD, with a HfO2 layer 23, which will serve as a gate oxide film, and a work function metal TiN layer 24, which will serve as a gate electrode, and a W layer 26. As illustrated in FIGS. 1KCA to 1KCC and FIGS. 1KEA to 1KEC, the entire surface is polished by CMP such that the upper surfaces of the HfO2 layer 23, the work function metal TiN layer 24, and the W layer 26 are flush with the upper surfaces of the mask semiconductor layers 7a, 7b, 7c, 7d, 7e, 7f, 7g, and 7h.

Next, the W layer 26, the TiN layer 24, and the HfO2 layer 23 are subjected to recess etching such that the upper surfaces of the W layer 26, the TiN layer 24, and the HfO2 layer 23 are positioned higher than the lower surfaces of the n⁺-layers 3a, 3c, 3b, and 3d, and the p⁺-layers 4a, 4b, 4c, and 4d. Next, the W layer 26, the TiN layer 24, and the HfO2 layer 23 are removed by photolithography and anisotropic etching to form a W layer 26aa and a TiN layer 24aa around the semiconductor pillar 6a, a W layer 26ab and a TiN layer 24ab around the semiconductor pillars 6b and 6c, a W layer 26ba and a TiN layer 24ba around the semiconductor pillars 6d and 6e, a W layer 26bb and a TiN layer 24bb around the semiconductor pillar 6f, a W layer 26g and a TiN layer 24g around the semiconductor pillar 6g, and a W layer 26h and a TiN layer 24h around the semiconductor pillar 6h. Next, the entire surface is covered with an interlayer insulating layer 25 made of SiO₂ according to, for example, FCVD, and as illustrated in FIGS. 1LCA to 1LCC and FIGS. 1LEA to 1LEC, the entire surface is polished by CMP such that the upper surface of the interlayer insulating layer 25 is flush with the upper surfaces of the mask semiconductor layers 7a, 7b, 7c, 7d, 7e, 7f, 7g, and 7h.

Next, resist opening regions are formed above a boundary between the n⁺-layer 3a and the p⁺-layer 4a in plan view, above the p⁺-layer 4g, and above a p⁺-layer 4h by lithography. The interlayer insulating layer 25, the inter-element insulating layer 14, and semiconductor pillar protective films 12a, 12b, 12g, and 12h are anisotropically etched. Next, a barrier metal 27 for contact holes and a W layer 29 are sequentially deposited, and as illustrated in FIGS. 1MCA to 1MCC and FIGS. 1MEA to 1MEC, the entire surface is polished by CMP such that the upper surfaces of the barrier metal 27 and the W layer 29 are flush with the upper surfaces of the interlayer insulating layer 25 to form barrier metals 27a, 27b, 27g, 27h, W29a, W29b, W29g, and W29h, which will serve as contact hole metals.

Next, the entire surface is covered with an interlayer insulating film 30 formed by CVD, and photoresist opening regions are formed above the mask semiconductor layers 7a, 7b, 7c, 7d, 7e, 7f, 7g, and 7h by lithography (not shown), which is used as a mask to etch the interlayer insulating film 30 by RIE and thus to expose the mask semiconductor layers 7a, 7b, 7c, 7d, 7e, 7f, 7g, and 7h (not shown). The exposed mask semiconductor layers 7a, 7b, 7c, 7d, 7e, 7f, 7g, and 7h are removed. Next, the entire surface is covered with a barrier metal for forming an upper electrode (not shown) and a W layer 33, and as illustrated in FIGS. 1NCA to 1NCC and FIGS. 1NEA to 1NEC, the entire surface is polished by CMP such that the upper surface of the barrier metal and the W layer 33 are flush with the upper surface of the interlayer insulating film 30 to form 33a, 33b, 33c, 33d, 33e, 33f, 33g, and 33h.

This process involves: forming the thin TiN layer and the W layer before forming the SiO₂ layer 30; etching the TiN layer and the W layer such that the TiN layer and the W layer remain on at least part of 8a, 8c, 8d, 8f, 9b, 9e, 9g, and 9h according to lithography and anisotropic etching to form 33a, 33b, 33c, 33d, 33e, 33f, 33g, and 33h; then covering the entire surface with the SiO₂ layer 30 by CVD; and polishing the entire surface by CMP. At this time, the amount of stock removal may be such that the surface is polished until the surface of the W layer is exposed or such that the SiO₂ layer 30 remains on the W layer.

Next, a connection wiring metal layer XC1 is formed via a contact hole C1 formed on the W layer 29a of the contact hole and on the W layer 26ba. At the same time, a connection wiring metal layer XC2 (not shown) is formed via a contact hole C2 formed on the W layer 29b of the contact hole and on the W layer 26ab, a source/drain wiring metal layer SD1 is formed via a contact hole V1 formed on the W layer 29g of the contact hole, and a source/drain wiring metal layer SD2 (not shown) is formed via a contact hole V2 formed on the W layer 29h of the contact hole.

A SiO₂ layer 36 having a flat upper surface is then formed to cover the entire surface. Next, a word wiring metal layer WL is formed via contact holes C3 and C4 formed on the W layers 26aa and 26bb. At the same time, gate wiring metal layers G1 and G2 are formed via contact holes V3 and V4 formed on the W layers 26g and 26h.

Next, a SiO₂ layer 37 having a flat upper surface is formed to cover the entire surface. A power supply wiring metal layer Vdd is formed via contact holes C5 and C6 formed on the W layers 33b and 33e on the p⁺-layers 9b and 9e. At the same time, source/drain wiring metal layers SD3 and SD4 are formed via contact holes V5 and V6 formed on the w layers 33g and 33h.

Next, a SiO₂ layer 38 having a flat upper surface is formed to cover the entire surface. A ground wiring metal layer Vss1 is then formed via a contact hole C7 formed on the W layer 33c on an n⁺-layer 8c, and a ground wiring metal layer Vss2 is formed via a contact hole C8 formed on the W layer 33d on an n⁺-layer 8d.

Next, a SiO₂ layer 39 having a flat upper surface is formed to cover the entire surface. A bit output wiring metal layer BL and a reverse bit output wiring metal layer RBL are then formed via contact holes C9 and C10 formed on the W layers 33a and 33f on n⁺-layers 8a and 8f. Accordingly, the RAM cell circuit including load SGTs at the Si pillars 6b and 6e, drive SGTs at the Si pillars 6c and 6d, and selection SGTs at the Si pillars 6a and 6f is formed on the p-layer substrate 1 as illustrated in FIGS. 1PCA to 1PCC, and the logic circuit is formed on the p-layer substrate 1 as illustrated in FIGS. 1PEA to 1PEC.

As illustrated in FIGS. 1PCA to 1PCC, the n⁺-layers 3a, 3c, 3d, and 3f and the p⁺-layers 4b and 4e, which will serve as sources or drains of SGTs, are formed below the Si pillars 6a to 6f and connected to each other on the n-layers 2a and 2b. Alternatively, the n⁺-layers 3a, 3c, 3d, and 3f, and the pt-layers 4b and 4e may be formed at the bottom portions of the Si pillars 6a to 6f, and the n⁺-layers 3a, 3c, 3d, and 3f, and the p⁺-layers 4b and 4e may be connected to each other with a metal layer or an alloy layer therebetween. The n⁺-layers 3a, 3c, 3d, and 3f, and the p⁺-layers 4b and 4e may be formed so as to be connected to the side surfaces of the bottom portions of the Si pillars 6a to 6f. Similarly, as illustrated in FIGS. 1PEA to 1PEC, the pt-layers 4g and 4h may be formed at the bottom portions of the Si pillars 6g and 6h and surrounded by a metal layer or an alloy layer, or the p⁺-layers 4g and 4h may be formed so as to be connected to the side surfaces of the bottom portions of the Si pillars 6g and 6h. As described above, the n⁺-layers 3a, 3c, 3d, and 3f, and the p⁺-layer 4b, 4e, 4g, and 4h, which will serve as sources or drains of SGTs, may be formed inside the bottom portions of the Si pillars 6a to 6h or on the outer peripheries of the Si pillars 6a to 6h so as to be in contact with the outside of their side surfaces. The n⁺-layers 3a, 3c, 3d, and 3f, and the p⁺-layer 4b, 4e, 4g, and 4h may be electrically connected to each other through other conductor materials. The same applies to other embodiments according to the present invention.

A memory cell includes circular SGTs (CSGTs) to reduce the memory cell area and increase the degree of integration, whereas a peripheral circuit, which requires current drive capability, needs to include multiple CSGTs connected in parallel to compensate for insufficient current drive capability. However, this configuration requires a significant large area and hinders high integration. To solve this, an elongated SGT (ESGT) has been proposed.

However, mounting both CSGTs and ESGTs causes the following issues.

### Issue 1.

CSGTs are used in memory cells and regularly arranged while having a fine semiconductor pillar shape with the same diameter. Self-aligned double patterning (SADP) commonly used in miniaturization processing is used for CSGTs. ESGTs are used in peripheral circuits and randomly arranged while having various SGT lengths and widths. Optimal processing is difficult with SADP.

### Issue 2.

There may be some method for forming CSGTs and ESGTs separately, but this method significantly increases the number of masks used and the number of steps, resulting in low throughput or high production costs.

The production method according to the first embodiment has the following features regarding the above issues.

1. SADP used for CSGTs involves performing patterning 2 times in total, patterning in the X-direction and the Y-direction perpendicular to each other, and forms CSGTs in overlaps of band-shaped sidewalls each formed in each patterning. For ESGTs, two rectangular frame-shaped sidewalls are formed at desired positions, and ESGTs are formed in overlaps of the sidewalls. This enables formation of both CSGTs and ESGTs in the same production process under the same production conditions.

2. There is no need of additional masks and additional steps, and it is thus possible to avoid low throughput, low yield, high production costs, and other problems.

3. In this embodiment, the SRAM cell including six SGTs is described for CSGTs, and the PMOS used in a logic circuit is described for ESGTs. In the former case, the present invention can also be applied to an SRAM cell including eight SGTs. In the latter case, the present invention can also be applied to an NMOS. For example, an inverter circuit, which is most commonly used, includes at least two transistors: n-channel and p-channel transistors. The degree of integration can be increased by forming the n-channel and p-channel transistors by using ESGTs, and a high-density microprocessor circuit can be achieved by applying the present invention to a microprocessor circuit including an SRAM cell region and a logic circuit region.

### Second Embodiment

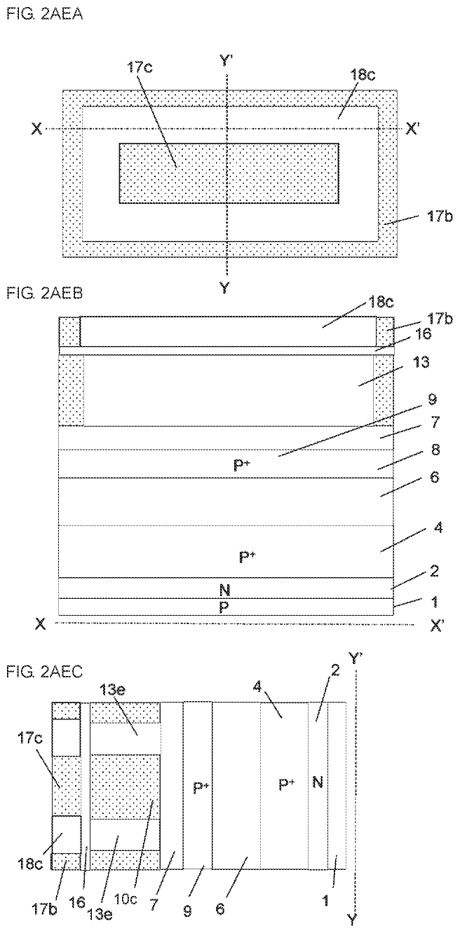

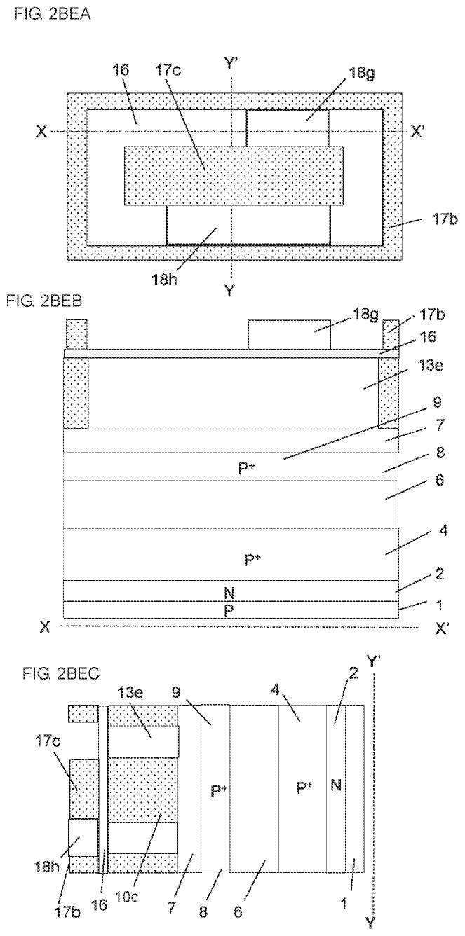

A method for producing ESGTs of PMOS used in a logic circuit as an example having SGTs according to a second embodiment of the present invention will be described below with reference to FIGS. 2AEA to 2AEC and FIGS. 2BEA to 2BEC. FIGS. 2AEA and 2BEA are plan views of a PMOS. FIGS. 2AEB and 2BEB are cross-sectional views taken along line X-X′ in FIGS. 2AEA and 2BEA. FIGS. 2AEC and 2BEC are cross-sectional views taken along line Y-Y′ in FIGS. 2AEA and 2BEA.

The steps in FIG. 1AEA to FIG. 1DEC according to the first embodiment are performed. Next, as illustrated in FIGS. 2AEA to 2AEC, the entire surface is covered with a hard mask layer 16 made of SiN and a support layer 17 made of SiO₂ according to, for example, CVD. The SiO₂ support layer 17 is etched by using, as masks, a resist layer (not shown) covering at least part of a support layer 10c made of SiO₂ and a resist layer (not shown) having a rectangular opening such that a sidewall 13e in the lower layer is exposed through the hard mask layer 16 in plan view, the resist layers being formed by lithography, to form a SiO₂ support layer 17b having a rectangular frame shape and a SiO₂ support layer 17c having a rectangular shape in plan view. Next, the entire surface is covered with an amorphous Si-hard mask layer 18 (not shown) so that a space between the support layers 17b and 17c is embedded in the amorphous Si-hard mask layer 18. The amorphous Si-hard mask layer 18 is anisotropically etched to remove the amorphous Si-hard mask layer 18 on the support layers 17b and 17c, so that the space between the support layers 17b and 17c is filled with an amorphous Si-hard mask layer 18c.

Next, as illustrated in FIGS. 2BEA to 2BEC, the sidewall formed by lithography in predetermined regions for forming semiconductor pillars is covered with a resist layer (not shown), and the sidewall 18c is anisotropically etched away to form sidewalls 18g and 18h.

The subsequent steps are the same as the steps in FIGS. 1GEA to 1GEC and the following figures in the first embodiment.

This embodiment has the following features.

The width of the ESGTs is determined by the width of the overlap of the sidewalls 13e and 18c. In this embodiment, the entire region of the sidewall 13e can be covered with the sidewall 18c regardless of misalignment caused by lithography, and the width of the ESGTs is thus determined only by the width of the sidewall 13e. This prevents or reduces variations in the width of the ESGT.

### Third Embodiment

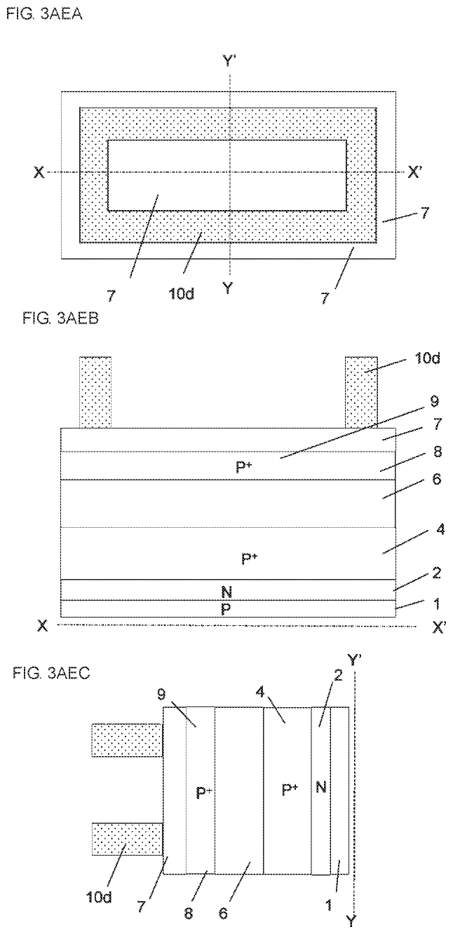

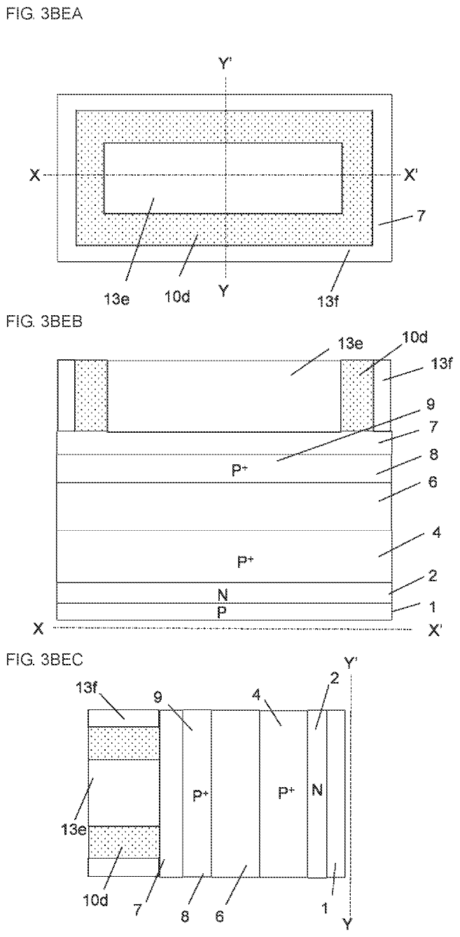

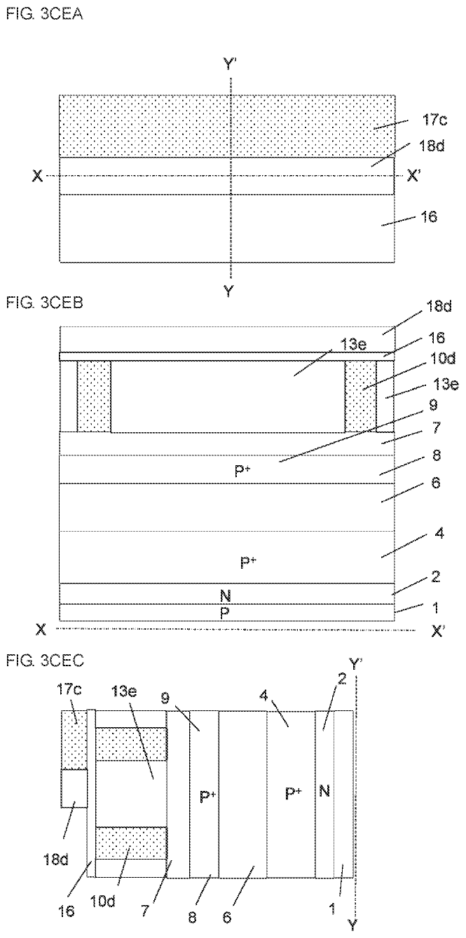

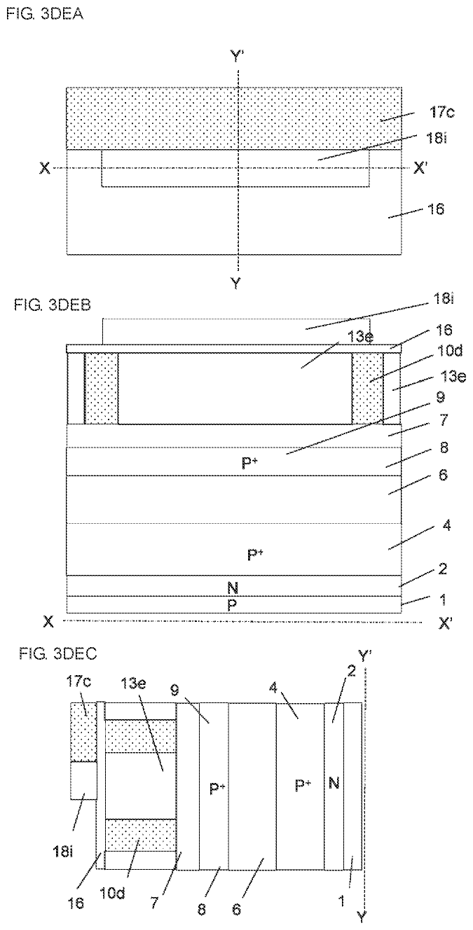

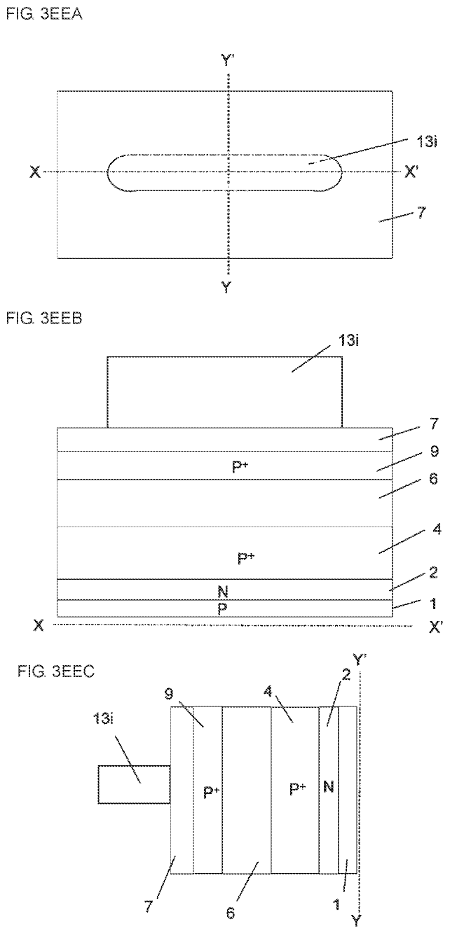

A method for producing an ESGT of PMOS used in a logic circuit as an example having an SGT according to a third embodiment of the present invention will be described below with reference to FIGS. 3AEA to 3EEC. FIGS. 3AEA, 3BEA, 3CEA, 3DEA, and 3EEA are plan views of a PMOS. FIGS. 3AEB, 3BEB, 3CEB, 3DEB, and 3EEB are cross-sectional views taken along line X-X′ in FIGS. 3AEA, 3BEA, 3CEA, 3DEA, and 3EEA. FIGS. 3AEC, 3BEC, 3CEC, 3DEC, and 3EEC are cross-sectional views taken along line Y-Y′ in FIGS. 3AEA, 3BEA, 3CEA, 3DEA, and 3EEA.

The step in FIGS. 1AEA to 1AEC in the first embodiment is performed, and as illustrated in FIGS. 3AEA to 3AEC, the SiO₂ support layer 10 is next etched by using, as a mask, a resist layer (not shown) having a rectangular frame shape in plan view and formed by lithography to form a SiO₂ support layer 10d having a rectangular frame shape in plan view.

Next, the entire surface is covered with a hard mask layer 13 (not shown) made of amorphous Si according to, for example, CVD so that the space inside the inner frame of the SiO₂ support layer 10d is embedded in the amorphous Si-hard mask layer 13. As illustrated in FIGS. 3BEA to 3BEC, the amorphous Si-hard mask layer 13 on the SiO₂ support layer 10d is anisotropically etched away, so that the space inside the inner frame of the SiO₂ support layer 10d is filled with the amorphous Si-hard mask layer 13e.

Next, the entire surface is covered with an insulating layer made of SiO₂ according to, for example, CVD, and the insulating layer 15 is polished by CMP until the top portion of the amorphous Si-hard mask layer 13e is exposed. Next, the entire surface is covered with a hard mask layer 16 made of SiN and a support layer 17 made of SiO₂ according to, for example, CVD. The SiO₂ support layer 17 is etched by using, as a mask, a band-shaped resist layer (not shown) formed by lithography and extending in the X-direction so as to run along the SiO₂ support layer 10d having a rectangular frame shape in plan view to form a band-shaped SiO₂ support layer 17c. Next, the entire surface is covered with a hard mask layer 18 (not shown) made of amorphous Si according to, for example, CVD, and as illustrated in FIGS. 3CEA to 3CEC, the amorphous Si-hard mask layer 18 is anisotropically etched away to form a sidewall 18d made of amorphous Si and located on the side wall of the band-shaped SiO₂ support layer 17c.

Next, as illustrated in FIGS. 3DEA to 3DEC, the sidewall 18d formed by lithography in a predetermined region for forming an ESGT is covered with a resist layer (not shown) such that the edges in the Y-direction are positioned above the SiO₂ support layer 10d. The sidewall 18d is anisotropically etched away, and the resist layer is stripped.

Next, as illustrated in FIGS. 3EEA to 3EEC, the support layer 17c is removed, and the hard mask layer 16 and the sidewall 13e are sequentially anisotropically etched by using the sidewall 18d as a mask to remove the SiO₂ support layer 10d and the SiO₂ insulating layer 15.

The subsequent steps are the same as the steps in FIGS. 1HEA to 1HEC and the following figures in the first embodiment.

This embodiment has the following features.

The length and width of the ESGT are determined by the overlap of the sidewalls 13e and 18c in the first embodiment. In this embodiment, the entire region of the sidewall 18d overlaps the sidewall 13e regardless of misalignment caused by lithography. The length of the ESGT is thus determined by the inner diameter of the support layer 13e, and the width of the ESGT is determined by the width of the sidewall 18d. This prevents or reduces variations in both the length and width of the ESGT.

### Fourth Embodiment

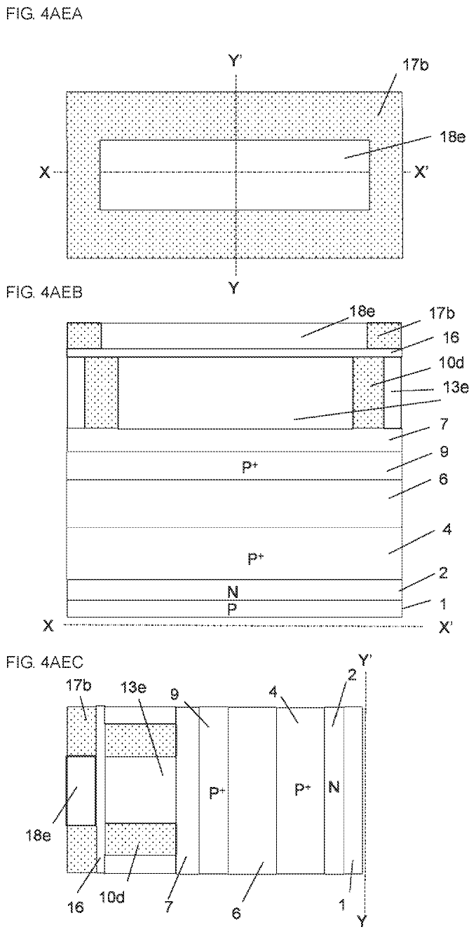

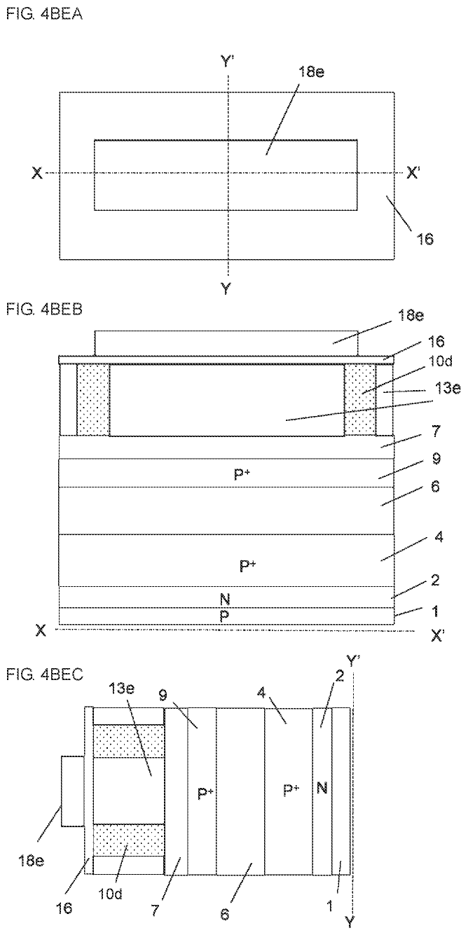

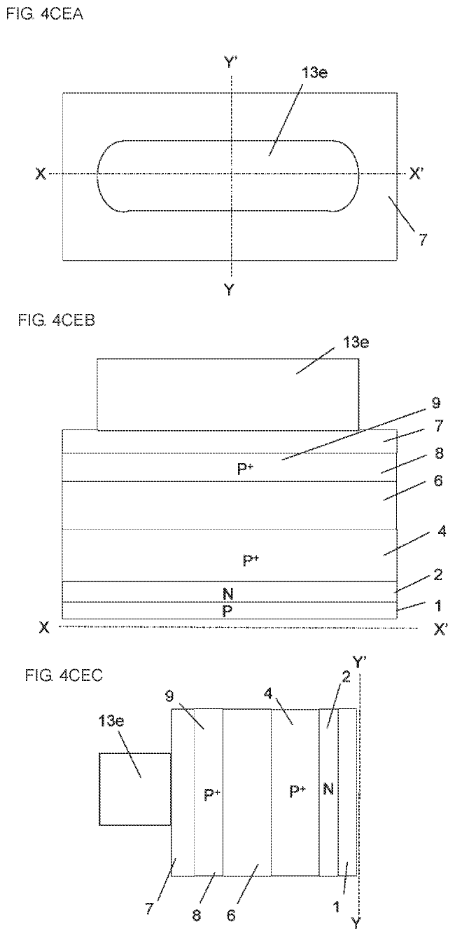

A method for producing an ESGT of PMOS used in a logic circuit as an example having an SGT according to a fourth embodiment of the present invention will be described below with reference to FIGS. 4AEA to 4CEC. FIGS. 4AEA, 4BEA, and 4CEA are plan views of PMOS. FIGS. 4AEB, 4BEB, and 4CEB are cross-sectional views taken along line X-X′ in FIGS. 4AEA, 4BEA, and 4CEA. FIGS. 4AEC, 4BEC, and 4CEC are cross-sectional views taken along line Y-Y′ in FIGS. 4AEA, 4BEA, and 4CEA.

The step in FIG. 3BEA to FIG. 3BEC in the third embodiment is performed. Next, as illustrated in FIGS. 4AEA to 4AEC, the entire surface is covered with a hard mask layer 16 made of SiN and a support layer 17 made of SiO₂ according to, for example, CVD. The SiO₂ support layer 17 is etched by using, as a mask, a rectangular frame-shaped resist layer (not shown) formed by lithography and covering the SiO₂ support layer 10d with the SiN hard mask layer 16 therebetween in plan view to form a SiO₂ support layer 17b having a rectangular frame shape. Next, the entire surface is covered with a hard mask layer 18 (not shown) made of amorphous Si according to, for example, CVD so that the space inside the rectangular frame of the SiO₂ support layer 17b is embedded in the amorphous Si-hard mask layer 18. As illustrated in FIGS. 4AEA to 4AEC, the amorphous Si-hard mask layer 18 on the SiO₂ support layer 17b is anisotropically etched away, so that the space inside the inner frame of the rectangular frame-shaped SiO₂ support layer 17b is filled with an amorphous Si-hard mask layer 18e.

Next, as illustrated in FIGS. 4BEA to 4BEC, the SiO₂ support layer 17b is removed.

Next, as illustrated in FIGS. 4CEA to 4CEC, the hard mask layer 16 and the sidewall 13e are sequentially anisotropically etched by using the amorphous Si-hard mask layer 18e as a mask to remove the SiO₂ support layer 10d and the SiO₂ insulating layer 15.

The subsequent steps are the same as the steps in FIGS. 1HEA to 1HEC and the following figures in the first embodiment.

This embodiment has the following features.

Since the width of the ESGT is determined by the width of the sidewall formed by SADP, only one type of width can be formed. However, by reducing the support layer space and filling the amorphous Si-hard mask layer 18 without forming a sidewall, the width of the ESGT can be freely set in a range of twice the sidewall width or less, and two or more types of width can be set as the width of the ESGT.

In the embodiments according to the present invention, one SGT is formed in one semiconductor pillar. However, the present invention can be applied to circuit formation for forming two or more SGTs in one semiconductor pillar.

In the first embodiment, the semiconductor pillars 6a to 6h are formed. However, the semiconductor pillars may be made of other semiconductor materials. The same applies to other embodiments according to the present invention.

The n⁺-layers 3a, 3c, 3d, 3f, 8a, 8c, 8d, and 8f, and the p⁺-layers 4a, 4b, 4g, 4h, 9b, 9e, 9g, and 9h in the first embodiment may be Si— or other semiconductor material layers containing a donor or acceptor impurity. The same applies to other embodiments according to the present invention.

In the first embodiment, the SiN layer 12 around the semiconductor pillars 6a to 6h may be another material layer containing an organic material or an inorganic material and composed of one layer or two or more layers as long as the material is suitable for the purpose of the present invention. The same applies to other embodiments according to the present invention.

In the first embodiment, the mask material layer 7 is formed of the SiN layer. The mask material layer 7 may be another material layer containing an organic material or an inorganic material and composed of one layer or two or more layers as long as the material is suitable for the purpose of the present invention. The same applies to other embodiments according to the present invention.

In the first embodiment, the wiring metal layers XC1, XC2, WL, Vdd, Vss, BL, RBL, SD1, SD2, SD3, SD4, G1, and G2 are not necessarily metal layers, and may be alloy layers, semiconductor layers containing a large amount of acceptor or donor impurity, or other conductive material layers, and may be composed of one layer or a combination of two or more layers. The same applies to other embodiments according to the present invention.

In the first embodiment, as illustrated in FIGS. 1LCA to 1LEC, the TiN layers 24aa, 24ab, 24ba, 24bb, 24g, and 24h are used as gate metal layers. The TiN layers may be material layers composed of one layer or two or more layers as long as the material is suitable for the purpose of the present invention. The TiN layers 24aa, 24ab, 24ba, 24bb, 24g, and 24h can be formed of conductor layers, such as metal layers each composed of one layer or two or more layers and having at least a desired work function. For example, a W layer or another conductor layer may be formed outside the TiN layers. In this case, the W layer functions as a metal wiring layer connecting the gate metal layers. A metal layer composed of one layer or two or more layers may be used in addition to the W layer. The HfO2 layer 23 is used as a gate insulating layer, but the HfO2 layer 23 may be another material layer composed of one layer or two or more layers. The same applies to other embodiments according to the present invention.

In the first embodiment, the semiconductor pillars 6a to 6f have a circular shape in plan view. Some or all of the semiconductor pillars 6a to 6f can easily be formed in a circular shape, an elliptical shape, a shape elongated in one direction, or other shapes in plan view. In a logic circuit region formed away from the SRAM area, semiconductor pillars having different shapes in plan view can be mixed and formed in the logic circuit region according to the logic circuit design. The same applies to other embodiments according to the present invention.

In the first embodiment, the n⁺-layers 3a, 3c, 3d, and 3f, and the p⁺-layers 4a, 4b, 4g, and 4h are formed so as to be connected to the bottom portions of the semiconductor pillars 6a to 6h. An alloy layer made of metal silicide or other materials may be formed on the upper surfaces of the n⁺-layers 3a, 3c, 3d, and 3f, and the p⁺-layers 4a, 4b, 4g, and 4h. As described above, the formation of the impurity regions connected to the bottom portions of the semiconductor pillars 6a to 6h and the formation of impurity layer-bonding regions that connect these impurity layers may be determined from a design and production standpoint. The same applies to other embodiments according to the present invention.

In the first embodiment, the SGTs are formed on the p-layer substrate 1. The p-layer substrate 1 may be replaced by a silicon-on-insulator (SOI) substrate. Alternatively, another material substrate may be used as long as it functions as a substrate. The same applies to other embodiments according to the present invention.

In the first embodiment, the SGTs include, as sources and drains on and below the semiconductor pillars 6a to 6h, the following layers having conductivity of the same polarity: the n⁺-layers 3a, 3c, 3d, and 3f and the p⁺-layers 4a, 4b, 4g, and 4h, and the n⁺-layers 8a, 8c, 8d, and 8f, and the p⁺-layers 9b, 9e, 9g, and 9h. The present invention can also be applied to tunnel-type SGTs including sources and drains with opposite polarities. The same applies to other embodiments according to the present invention.

A vertical NAND-type flash memory circuit includes multiple layers of memory cells stacked vertically, wherein the memory cells each include a semiconductor pillar as a channel and include, around the semiconductor pillar, a tunnel oxide layer, a charge storage layer, an interlayer insulating layer, and a control conductor layer. The semiconductor pillars at both ends of these memory cells have a source line impurity layer corresponding to a source and a bit line impurity layer corresponding to a drain. When one of memory cells on both sides of a certain memory cell functions as a source, the other functions as a drain. For this, the vertical NAND-type flash memory circuit is one of SGT circuits. Therefore, the present invention can also be applied to a circuit mixed with a NAND-type flash memory circuit.

Similarly, the present invention can also be applied not only to magnetic memory circuits and ferroelectric memory circuits, but also to inverters and logic circuits used inside and outside the memory cell area.

Various embodiments and modifications can be made in the present invention without departing from the broad spirit and scope of the present invention. The embodiments described above are for illustrating embodiments of the present invention and do not limit the scope of the present invention. The embodiments described above and modifications can be freely combined with each other. Even if some elements are removed from the embodiments as necessary, the embodiments are also within the technical idea of the present invention.

According to the method for producing a pillar-shaped semiconductor device according to the present invention, a high-density pillar-shaped semiconductor device is produced.

What is claimed is:

1. A method for producing a pillar-shaped semiconductor device having both a circular SGT (CSGT) and an elongated SGT (ESGT) on a substrate,
wherein the pillar-shaped semiconductor device includes: on the substrate, a first semiconductor pillar region having a first semiconductor pillar with a CSGT shape, and a second semiconductor pillar region having a second semiconductor pillar with an ESGT shape; a first gate insulating layer around the first semiconductor pillar; a second gate insulating layer around the second semiconductor pillar; a first gate conductor layer around the first gate insulating layer; a second gate conductor layer around the second gate insulating layer; a first impurity region connected to a lower portion of the first semiconductor pillar; a second impurity region connected to a lower portion of the second semiconductor pillar; a third impurity region connected to a top portion of the first semiconductor pillar; and a fourth impurity region connected to a top portion of the second semiconductor pillar, and
the pillar-shaped semiconductor device has: a first SGT in which the first semiconductor pillar between the first impurity region and the third impurity region is a channel; and a second SGT in which the second semiconductor pillar between the second impurity region and the fourth impurity region is a channel,
wherein the method comprises:
a step of forming, on a surface of the substrate, the first impurity region and the second impurity region each containing a donor or acceptor impurity;
a step of forming a semiconductor pillar layer, which will serve as the first and second semiconductor pillars, on the first impurity region and the second impurity region to cover an entire surface, and forming the third impurity region and the fourth impurity region on the semiconductor pillar layer;
a step of forming a first hard mask layer on the third impurity region and the fourth impurity region to cover an entire surface;
a step of forming a first support layer in a band shape in plan view on the first hard mask layer on the first semiconductor pillar region, and forming a second support layer in a rectangular shape in plan view on the first hard mask layer on the second semiconductor pillar region;
a step of forming a second hard mask layer to cover an entire surface;
a step of anisotropically etching the second hard mask layer to form first sidewalls composed of the second hard mask layer and located on side walls of the first and second support layers;
a step of forming a first insulating layer to cover an entire surface;
a step of polishing the first insulating layer until surfaces of top portions of the first and second support layers are exposed;
a step of forming a third hard mask layer to cover an entire surface;
a step of forming a third support layer on the third hard mask layer in the first semiconductor pillar region such that the third support layer has a band shape so as to perpendicularly cross the first support layer in plan view, and forming a fourth support layer on the third hard mask layer in the second semiconductor pillar region such that the fourth support layer has a rectangular opening inside so as to surround the first sidewall in plan view;
a step of forming a fourth hard mask layer to cover an entire surface;
a step of anisotropically etching the fourth hard mask layer to form second sidewalls composed of the fourth hard mask layer and located on side walls of the third and fourth support layer;
a step of forming, by photolithography, a photoresist above the first semiconductor pillar region so as to cover the second sidewall in a region for forming the CSGT and forming the photoresist above the second semiconductor pillar region so as to cover the second sidewall in a region for forming the ESGT;
a step of anisotropically etching the exposed second sidewalls away and stripping the photoresist;
a step of removing the third and fourth support layers and sequentially anisotropically etching the third hard mask layer and the first sidewalls by using the remaining second sidewalls as a mask to remove the first insulating layer, the first support layer, and the second support layer;
a step of sequentially anisotropically etching the first hard mask layer, the third impurity region and the fourth impurity region, the semiconductor pillar layer, and the first impurity region and the second impurity region by using the remaining first sidewalls as a mask to form the first semiconductor pillar and the second semiconductor pillar;
a step of forming the first gate insulating layer around the first semiconductor pillar, and forming the second gate insulating layer around the second semiconductor pillar; and
a step of forming the first gate conductor layer around the first gate insulating layer, and forming the second gate conductor layer around the second gate insulating layer.

2. The method for producing a pillar-shaped semiconductor device according to claim 1, the method comprising:
after forming the third hard mask layer to cover the entire surface,
a step of forming the third support layer such that the third support layer has a band shape so as to perpendicularly cross the first support layer in plan view, and a step of forming the fourth support layer such that the fourth support layer has a rectangular opening inside so as to surround the first sidewall and forming a fifth support layer inside the first sidewall such that the fifth support layer has a rectangular shape in plan view;
a step of forming the fourth hard mask layer to cover an entire surface so that a space between the fourth support layer and the fifth support layer in the second semiconductor pillar region is embedded in the fourth hard mask layer; and
a step of anisotropically etching the fourth hard mask layer to form the second sidewall composed of the fourth hard mask layer and located on a side wall of the third support layer, and removing the fourth hard mask layer on the fourth and fifth support layers so that the space between the fourth support layer and the fifth support layer is filled with the fourth hard mask layer.

3. The method for producing a pillar-shaped semiconductor device according to claim 1, the method comprising:
a step of forming the second support layer in a rectangular frame shape in plan view;
a step of forming the second hard mask layer to cover an entire surface so that a space inside an inner frame of the second support layer is embedded in the second hard mask layer;
a step of anisotropically etching the second hard mask layer to form the first sidewall composed of the second hard mask layer and located on a side wall of the first support layer and to fill the space inside the inner frame of the second support layer with the second hard mask layer;
a step of forming the first insulating layer to cover an entire surface;
a step of polishing the first insulating layer until a surface of a top portion of the second support layer is exposed;
a step of forming the third hard mask layer to cover an entire surface;
a step of forming the fourth support layer such that edges of the fourth support layer are positioned above the filled second hard mask layer in vertical view;
a step of forming the fourth hard mask layer to cover an entire surface; and
a step of anisotropically etching the fourth hard mask layer to form the second sidewall composed of the fourth hard mask layer and located on a side wall of the fourth support layer.

4. The method for producing a pillar-shaped semiconductor device according to claim 3, the method comprising:
after forming the third hard mask layer to cover the entire surface,
a step of forming the fourth support layer such that the fourth support layer has a rectangular opening such that at least part of the remaining first sidewall is exposed in plan view;
a step of forming the fourth hard mask layer to cover an entire surface; and
a step of anisotropically etching the fourth hard mask layer to form the second sidewall composed of the fourth hard mask layer and located on a side wall of the third support layer and to fill the opening of the fourth support layer with the fourth hard mask layer.
